(19) United States
(12) Patent Application Publication
(10) Pub. No.: US 2025/0343096 A1
(43) Pub. Date: Nov. 6, 2025

(54) SEMICONDUCTOR DEVICE PACKAGES AND METHODS OF FORMATION

(71) Applicant: Taiwan Semiconductor Manufacturing Company , Ltd., Hsinchu (TW)

(72) Inventors: Singda JIANG, Taichung City (TW); Shih-Wei LIU, Chiayi City (TW); Tsunyen WU, Hsinchu County (TW); Kathy Wei YAN, Hsinchu (TW)

(21) Appl. No.: 18/654,441

(22) Filed: May 3, 2024

(51) Int. Cl. H01L 23/367; H01L 21/56; H01L 23/00; H01L 23/373; H01L 25/065

(52) U.S. Cl. CPC H01L 23/3672; H01L 21/565; H01L 23/3736; H01L 24/16; H01L 24/32; H01L 24/73; H01L 25/0652; H01L 2224/16146; H01L 2224/16225; H01L 2224/32104; H01L 2224/32146; H01L 2224/73153; H01L 2924/0665; H01L 2924/1427; H01L 2924/1431; H01L 2924/182; H01L 2924/351

(57) ABSTRACT

Thermal management components are included over semiconductor components on both sides of a package substrate of a semiconductor device package to provide two-sided thermal management system for the semiconductor device package. The two-sided thermal management system of the semiconductor device package enables heat to be dissipated from the semiconductor components on both sides of the package substrate of the semiconductor device package. This enables the semiconductor components on both sides of the package substrate of the semiconductor device package to operate at lower temperatures, which may increase the performance of the semiconductor components, may enable the performance of the semiconductor components to be sustained for longer time durations, and/or may increase the reliability and longevity of the semiconductor components, among other examples.

### BACKGROUND

In the electronics industry, effective heat dissipation is essential to maintain optimal performance and reliability of semiconductor components in an electronics device such as a semiconductor device package. Thermal management of heat dissipation in a semiconductor device package generally includes various structures and techniques for moving heat away from (“cooling”) the semiconductor components in a semiconductor device package to reduce and/or minimize the thermal stress on the semiconductor components.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1E are diagrams of examples of a semiconductor device package described herein.

FIG. 2 is a diagram of an example of a thermal lid structure described herein.

FIG. 3 is a diagram of an example of a thermal lid structure described herein.

FIGS. 4A-4K are diagrams of an example of forming a semiconductor device package described herein.

FIGS. 5A and 5B are diagrams of an example of mounting a semiconductor device package described herein to a mounting structure.

FIGS. 6A and 6B are diagrams of examples of another semiconductor device package described herein.

FIGS. 7A and 7B are diagrams of examples of another semiconductor device package described herein.

FIG. 8 is a diagram of an example of another semiconductor device package described herein.

FIG. 9 is a diagram of an example of another semiconductor device package described herein.

FIG. 10 is a flowchart of an example process associated with forming a semiconductor device package described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A semiconductor device package is typically manufactured such that the semiconductor device package is capable of being mounted or attached to a mounting structure (e.g., a socket or printed circuit board (PCB), among other examples) on one side of the semiconductor device package. The other side of the semiconductor device package opposing the mounting structure provides an opportunity for thermal management in the semiconductor device package. In particular, various types of heatsinks, heat spreaders, fins, fans, and/or other thermal management components are often times included on this side of the semiconductor device package to remove heat that is generated by the semiconductor components of the semiconductor device package.

Some advanced packaging techniques for semiconductor device packages include mounting or attaching semiconductor components to opposing sides of a package substrate (e.g., an interposer, a redistribution layer (RDL)) of a semiconductor device package to enable an increased density of semiconductor components to be included in the semiconductor device package. In other words, semiconductor components are mounted or attached to a top side, as well as to a bottom side of the package substrate of the semiconductor device package. This results in at least a subset of the semiconductor components of the semiconductor device package being positioned between the package substrate and a mounting structure when the semiconductor device package is mounted or attached to the mounting structure. As a result, heat generated by these semiconductor components may become trapped between the package substrate and the mounting structure, resulting in prolonged exposure of the semiconductor components to high temperatures. This can cause the performance and/or reliability of the semiconductor components between the package substrate and the mounting structure to be reduced, and can result in premature failure of the semiconductor components.

In some implementations described herein, thermal management components are included over semiconductor components on both sides of a package substrate of a semiconductor device package to provide two-sided thermal management system for the semiconductor device package. Semiconductor components such as semiconductor dies may be mounted or attached to the top side of the package substrate, and semiconductor components such as integrated circuit devices (e.g., voltage regulator module (VRM) devices and/or other active integrated circuit devices) and/or integrated passive devices (IPDs) may be mounted or attached to the bottom side of the package substrate. Thermal management components such as heatsinks, fins, vapor chamber lid structures, and/or other types of thermal management components may be included over the semiconductor components on the top side and over the semiconductor components on the bottom side of the package substrate. For example, a first vapor chamber lid structure may be included over (and thermally coupled with) the semiconductor components on the top side of the package substrate, and a second vapor chamber lid structure may be included over (and thermally coupled with) the semiconductor components on the bottom side of the package substrate. The second vapor chamber lid structure may be sized such that the semiconductor components on the bottom side of the package structure and the associated second vapor chamber lid structure fit with package connectors of the semiconductor device package that are used to mount or attach the semiconductor device package to a mounting structure.

In this way, the two-sided thermal management system of the semiconductor device package enables heat to be dissipated from the semiconductor components on both sides of the package substrate of the semiconductor device package. This enables the semiconductor components on both sides of the package substrate of the semiconductor device package to operate at lower temperatures, which may increase the performance of the semiconductor components, may enable the performance of the semiconductor components to be sustained for longer time durations, and/or may increase the reliability and longevity of the semiconductor components, among other examples.

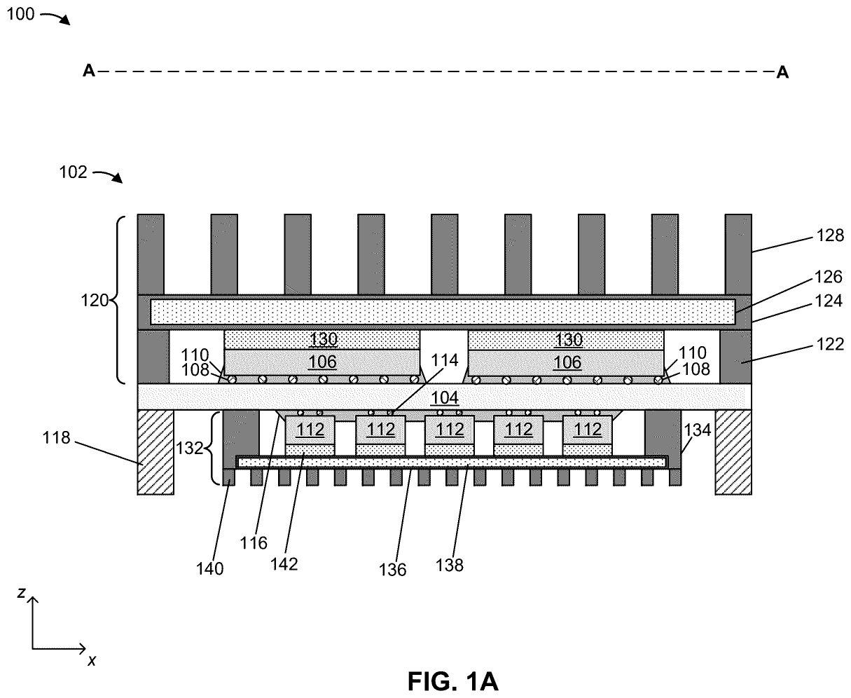

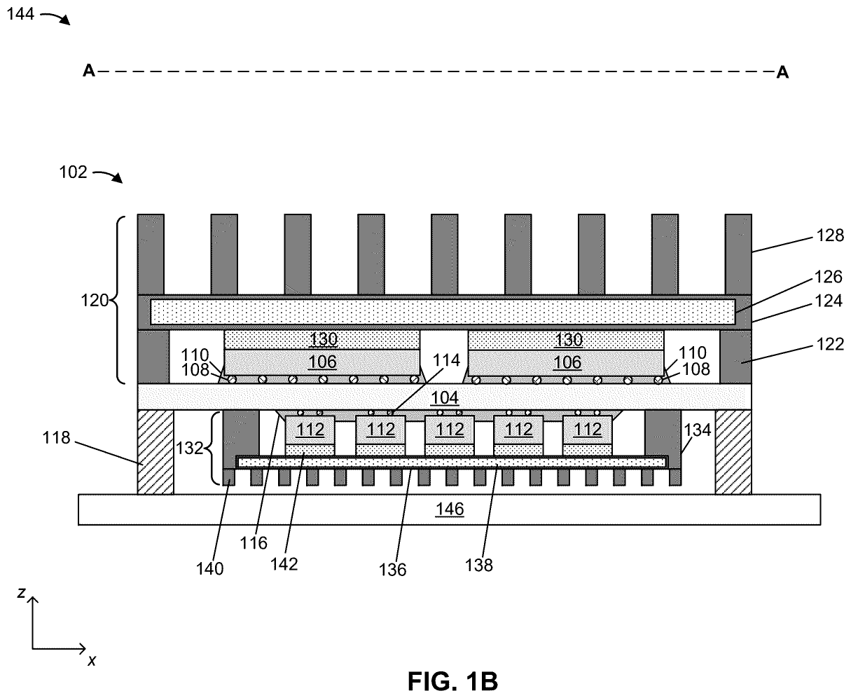

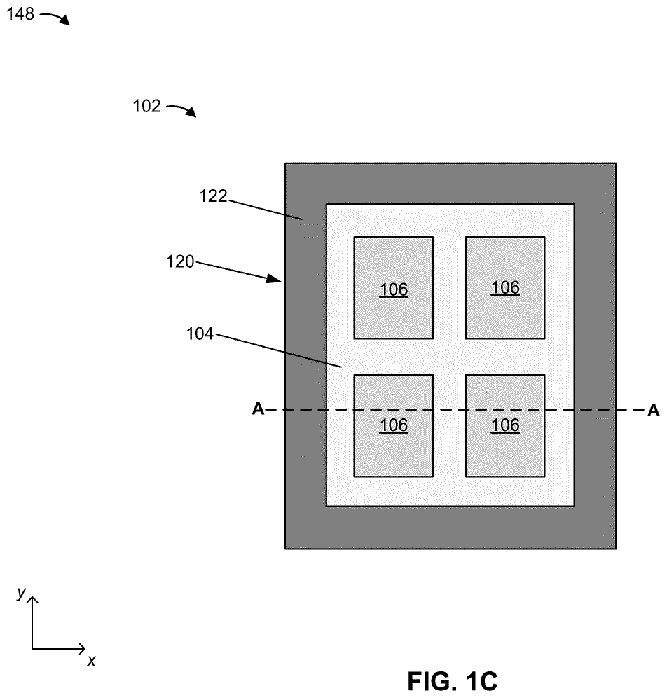

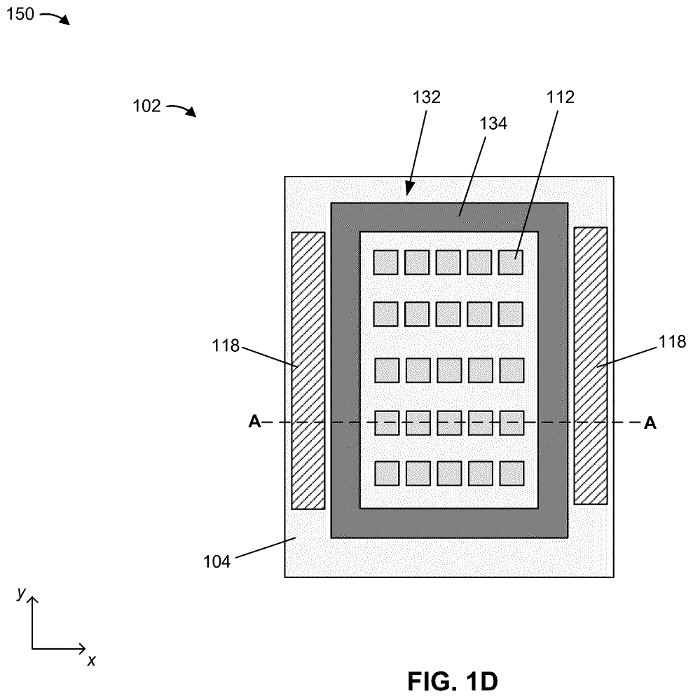

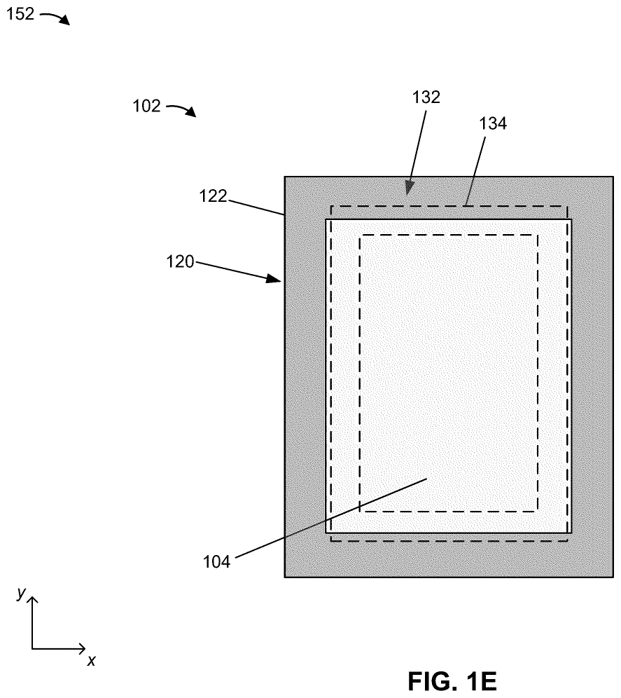

FIGS. 1A-1E are diagrams of examples of a semiconductor device package described herein. FIG. 1A illustrates a cross-section view of an example 100 of a semiconductor device package 102. The semiconductor device package 102 includes a package substrate 104 and one or more semiconductor dies 106 mounted or attached to a first side (e.g., a top side) of the package substrate 104. In some implementations, the semiconductor device package 102 includes a plurality of semiconductor dies 106 and is a multiple-die semiconductor device package. The plurality of semiconductor dies 106 may be horizontally arranged (e.g., in an x-direction, in a y-direction) in the semiconductor device package 102 and/or vertically arranged in a z-direction in the semiconductor device package 102.

The package substrate 104 includes a plurality of electrically conductive traces or layers that are interconnected and enable signals and/or power to be routed between the semiconductor dies 106 and/or to be routed between a semiconductor die 106 and devices external to the semiconductor device package 102. In some implementations, the package substrate 104 is an interposer, and includes a silicon (Si) interposer, an organic interposer (e.g., an organic polymer interposer), a dielectric interposer (e.g., a silicon oxide (SiOₓ) or glass interposer), and/or another type of interposer. The electrically conductive traces in the package substrate 104 may arranged in interconnected layers referred to as RDLs. Each RDL may include trenches, conductive lines, and/or other types of conductive structures that extend primarily laterally or horizontally (e.g., in the x-direction, in the y-direction) in the package substrate 104. The RDLs in the package substrate 104 may be interconnected by interconnect layers that includes vias, conductive pillars, conductive columns, and/or other types of interconnect structures that primarily vertically extend (e.g., in the z-direction) in the package substrate 104. The electrically conductive traces in the package substrate 104 may include one or more electrically conductive materials such as gold (Au), copper (Cu), silver (Ag), nickel (Ni), aluminum (Al), ruthenium (Ru), cobalt (Co), titanium (Ti), tungsten (W), tin (Sn), lead (Pb), and/or palladium (Pd), among other examples.

One or more types of semiconductor dies 106 may be include in the semiconductor device package 102. One or more of the semiconductor dies 106 may each include a system on chip (SoC) die, such as a logic die, a central processing unit (CPU) die, a graphics processing unit (GPU) die, a digital signal processing (DSP) die, an application specific integrated circuit (ASIC) die, and/or another type of SoC die. One or more of the semiconductor dies 106 may each include a memory die, an input/output (I/O) die, a pixel sensor die, a high voltage (HV) die, and/or another type of semiconductor die. One or more of the semiconductor dies 106 may each include a memory die, such as a static random access memory (SRAM) die, a dynamic random access memory (DRAM) die, a NAND die, a high bandwidth memory (HBM) die, and/or another type of memory die. In some implementations, one or more of the semiconductor dies 106 are included in a semiconductor die package in which the semiconductor die(s) 106 are packaged along with other components such as I/O and/or memory.

The semiconductor dies 106 may be mounted or attached to the first side of the package substrate 104 by connection structures 108. The connection structures 108 may include bonding pads, solder balls arranged in ball grid array (BGA), micro bumps, controlled collapse chip connection (C4) bumps, metal pads arranged in a land grid array (LGA), conductive pins arranged in a pin grid array (PGA), and/or another type of connection structures. In some implementations, the connection structures 108 include two or more types of connection structures.

Underfill layers 110 may be provided between the semiconductor dies 106 and the first side of the package substrate 104. The underfill layers 110 may be included between and around the connection structures 108, and may provide electrical isolation between the connection structures 108 as well as protection for the semiconductor dies 106 against vibration and humidity ingress. The underfill layers 110 may include an underfill material such as a polymer, one or more fillers dispersed in a resin, an epoxy-based resin, and/or another type of electrically insulating material. In some implementations, an encapsulant is provide around the semiconductor dies 106 above the underfill layers 110. The encapsulant may include a plastic molding compound and/or another type of encapsulant.

As further shown in FIG. 1A, integrated circuit devices 112 are mounted or attached to a second side (e.g., a bottom side) of the package substrate 104 vertically opposite the first side. Thus, components are mounted or attached to both sides of the package substrate 104, and the electrically conductive traces in the package substrate 104 may be configured to route signals and/or power between the semiconductor dies 106 and the integrated circuit devices 112 through the package substrate 104. In some implementations, one or more integrated circuit devices 112 include active circuit devices such as VRM integrated circuit devices that are configured to actively regulate the voltages provided to the semiconductor dies 106. In some implementations, one or more integrated circuit devices 112 include active electrostatic discharge (ESD) protection integrated circuit devices such as an ESD triggering circuit that is configured to redirect electrical power away from the semiconductor dies 106 and toward an ESD protection circuit in an overvoltage event or overcurrent event. In some implementations, one or more integrated circuit devices 112 include a power supply inverter circuit, an analog-to-digital converter circuit, and/or another type of integrated circuit device.

The integrated circuit devices 112 are mounted or attached to the second side of the

package substrate 104 by connection structures 114. The connection structures 114 may include bonding pads, solder balls, micro bumps, C4 bumps, metal pads, conductive pins, wire leads, and/or another type of connection structures. In some implementations, the connection structures 114 include two or more types of connection structures.

An underfill layer 116 may be provided between the integrated circuit devices 112 and the second side of the package substrate 104. The underfill layer 116 may be included between and around the connection structures 114, and may provide electrical isolation between the connection structures 114 as well as protection for the integrated circuit devices 112 against vibration and humidity ingress. The underfill layer 116 may include an underfill material such as a polymer, one or more fillers dispersed in a resin, an epoxy-based resin, and/or another type of electrically insulating material. In some implementations, an encapsulant is provide around the integrated circuit devices 112 above the underfill layer 116. The encapsulant may include a plastic molding compound and/or another type of encapsulant.

Package connectors 118 of the semiconductor device package 102 may be included on the second side of the package substrate 104. The package connectors 118 may include sockets, pins, contact pads on a substrate such as a PCB, and/or another type of package connectors that enable the semiconductor device package 102 to be mounted or attached to a mounting structure.

Referring to the first side of the package substrate 104, a thermal lid structure 120 is included above (and mounted or attached to) the first side of the package substrate 104. The thermal lid structure 120 is included over the semiconductor dies 106 and is thermally coupled with the semiconductor dies 106. This enables the thermal lid structure 120 to provide thermal management for the semiconductor dies 106. In particular, the thermal lid structure 120 may remove heat from the semiconductor dies 106 and/or from around the semiconductor dies 106, thereby providing cooling for the semiconductor dies 106.

The thermal lid structure 120 includes a footing 122 mounted or attached to the first side (e.g., the front side) of the package substrate 104. The package connectors 118 may be located under a portion of the first side of the package substrate 104 to which the footing 122 is coupled such that the footing 122 and each of the package connectors 118 are vertically arranged in the z-direction in the semiconductor device package 102. The footing 122 functions as a lid wall and supports a lid 124 of the thermal lid structure 120. The footing 122 may also function as a stiffener and may provide increased structural rigidity and support for the semiconductor device package 102. The lid 124 spans across the footing 122 and over the semiconductor dies 106 such that the lid 124 is thermally coupled with the semiconductor dies 106 (e.g., the sides of the semiconductor dies 106 opposing the sides of the semiconductor dies 106 that are mounted or attached to the first side of the package substrate 104).

In some implementations, a vapor chamber 126 is integrated into the lid 124. Thus, the thermal lid structure 120 may be referred to as a vapor chamber lid structure. Including the vapor chamber 126 within the lid 124, as opposed to including a separate vapor chamber heatsink on the thermal lid structure 120, reduces the vertical size (e.g., the height) of the semiconductor device package 102 and enables the vapor chamber 126 to be placed closer to the semiconductor dies 106. The closer placement of the vapor chamber 126 to the semiconductor dies 106 provides for increased thermal transfer between the semiconductor dies 106 and the vapor chamber 126 than if the vapor chamber 126 were located further away from the semiconductor dies 106 in a separate heatsink.

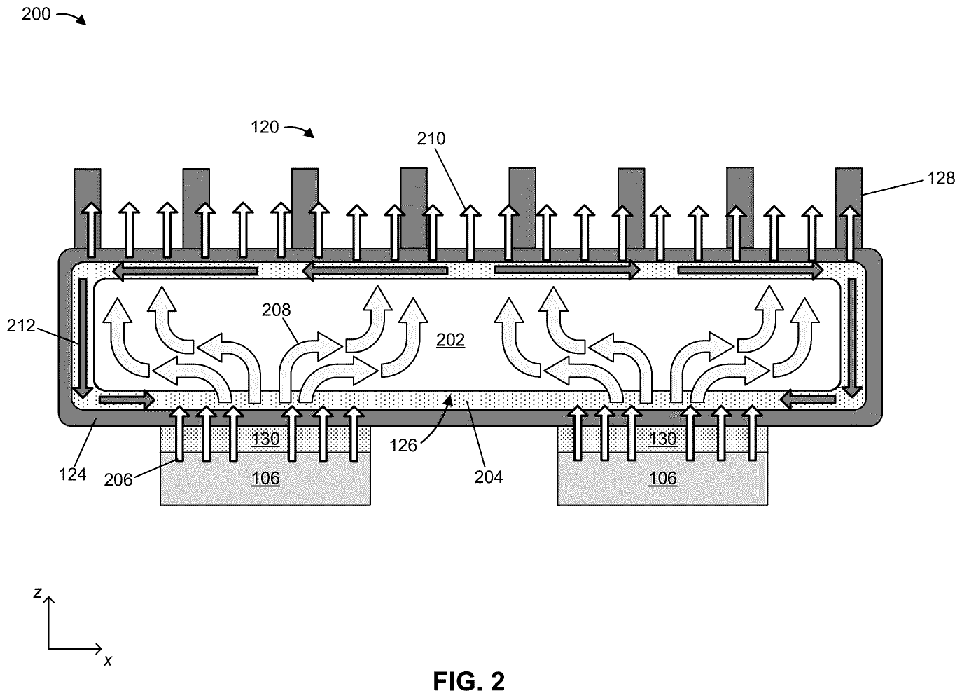

The vapor chamber 126 functions as a heat spreader and a heat exchanger in that the vapor chamber 126 extracts heat from the semiconductor dies 106 and spreads the heat across the lateral surface of the lid 124, thereby enabling a greater amount of surface area of the lid 124 to be used to exchange the heat from the lid 124 to fins 128 above the lid 124. The heat is then transferred from the fins 128 to the ambient environment around the semiconductor device package 102 and/or to an external heatsink device. The fins 128 are physically coupled to a side of the lid 124 opposite the side of the lid 124 to which the semiconductor dies 106 are thermally coupled. Including the fins 128 above the lid 124 provides increased surface area through which heat may be transferred to the environment around the semiconductor device package 102. In some implementations, fans may blow cold air across the fins 128 to facilitate the transfer of heat away from the fins. Additional details regarding the operation of the vapor chamber 126 are illustrated and described in connection with FIG. 2.

The footing 122, the lid 124, and the fins 128 may each be formed of the same material (or the same materials) or of different material(s). The footing 122, the lid 124, and the fins 128 may each be formed of a thermally conductive metal, such as aluminum (Al), copper (Cu), gold (Au), and/or silver (Ag), among other examples. Additionally and/or alternatively, the footing 122, the lid 124, and/or the fins 128 may one or more other materials having a high thermal conductivity (e.g., a thermal conductivity greater than aluminum), such as diamond, silicon carbide (SiC), and/or aluminum nitride (AlN), among other examples.

The top surfaces of the semiconductor dies 106 may be thermally coupled with the lid 124 of the thermal lid structure 120 through thermal interface material layers 130. Each thermal interface material layer 130 includes a layer of thermal interface material. The thermal interface material may include a thermal interface paste, a thermal interface sheet, and/or another type of thermal interface material. In some implementations, the thermal interface material of the thermal interface material layers 130 includes a paste that includes metal particles (e.g., gold particles, silver particles) suspended in a liquid compound. In some implementations, the thermal interface material of the thermal interface material layers 130 includes a graphene sheet and/or another type of carbon-based thermal interface material. In some implementations, the thermal interface material of the thermal interface material layers 130 includes a phase change material such as a polymer-based phase change material. In some implementations, the thermal interface material of the thermal interface material layers 130 includes a liquid metal thermal interface material, which may include one or more types of metals (e.g., gallium (Ga), indium (In), tin (Sn)) in liquid form suspended in a compound.

Referring to the second side of the package substrate 104, a thermal lid structure 132 is also included below (and mounted or attached to) the second side of the package substrate 104. The thermal lid structure 132 is included over the integrated circuit devices 112 and is thermally coupled with the integrated circuit devices 112. This enables the thermal lid structure 132 to provide thermal management for the integrated circuit devices 112. In particular, the thermal lid structure 132 may remove heat from the integrated circuit devices 112 and/or from around the integrated circuit devices 112, thereby providing cooling for the integrated circuit devices 112.

The thermal lid structure 132 includes a footing 134 mounted or attached to the second side (e.g., the back side) of the package substrate 104. The package connectors 118 may be located adjacent to one or more sides of the footing 134. The footing 134 functions as a lid wall and supports a lid 136 of the thermal lid structure 132. The footing 134 may also function as a stiffener and may provide increased structural rigidity and support for the semiconductor device package 102. The lid 136 spans across the footing 134 and over the integrated circuit devices 112 such that the lid 136 is thermally coupled with the integrated circuit devices 112 (e.g., the sides of the integrated circuit devices 112 opposing the sides of the integrated circuit devices 112 that are mounted or attached to the second side of the package substrate 104).

In some implementations, a vapor chamber 138 is integrated into the lid 136. Thus, the thermal lid structure 132 may be referred to as a vapor chamber lid structure. Including the vapor chamber 138 within the lid 136, as opposed to including a separate vapor chamber heatsink on the thermal lid structure 132, reduces the vertical size (e.g., the height) of the semiconductor device package 102 and enables the vapor chamber 138 to be placed closer to the integrated circuit devices 112. The closer placement of the vapor chamber 138 to the integrated circuit devices 112 provides for increased thermal transfer between the integrated circuit devices 112 and the vapor chamber 138 than if the vapor chamber 138 were located further away from the integrated circuit devices 112 in a separate heatsink. Moreover, the reduced vertical size of the semiconductor device package 102 enables the package connectors 118 to be shorter, which may reduce signal propagation distance in the semiconductor device package 102 and/or may reduce electrical resistance in the semiconductor device package 102.

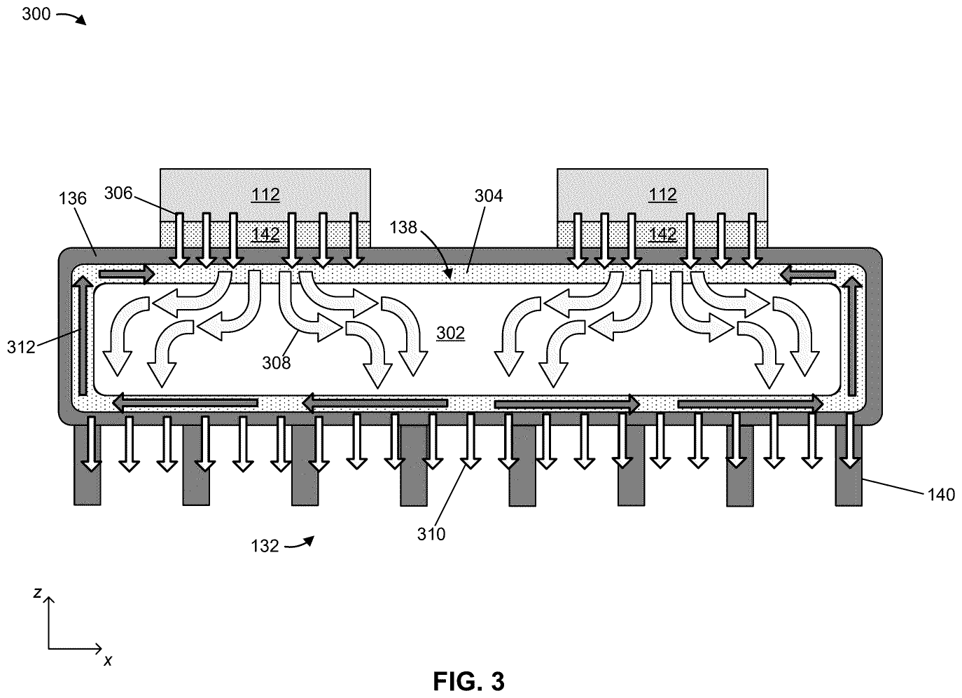

The vapor chamber 138 functions as a heat spreader and a heat exchanger in that the vapor chamber 138 extracts heat from the integrated circuit devices 112 and spreads the heat across the lateral surface of the lid 136, thereby enabling a greater amount of surface area of the lid 136 to be used to exchange the heat from the lid 136 to fins 140 above the lid 136. The heat is then transferred from the fins 140 to the ambient environment around the semiconductor device package 102. The fins 140 are physically coupled to a side of the lid 136 opposite the side of the lid 136 to which the integrated circuit devices 112 are thermally coupled. Including the fins 140 above the lid 136 provides increased surface area through which heat may be transferred to the environment around the semiconductor device package 102. Additional details regarding the operation of the vapor chamber 138 are illustrated and described in connection with FIG. 3.

The footing 134, the lid 136, and the fins 140 may each be formed of the same material (or the same materials) or of different material(s). The footing 134, the lid 136, and the fins 140 may each be formed of a thermally conductive metal, such as aluminum (Al), copper (Cu), gold (Au), and/or silver (Ag), among other examples. Additionally and/or alternatively, the footing 134, the lid 136, and/or the fins 140 may one or more other materials having a high thermal conductivity (e.g., a thermal conductivity greater than aluminum), such as diamond, silicon carbide (SiC), and/or aluminum nitride (AlN), among other examples.

The top surfaces of the integrated circuit devices 112 may be thermally coupled with the lid 136 of the thermal lid structure 132 through thermal interface material layers 142. Each thermal interface material layer 142 includes a layer of thermal interface material. The thermal interface material may include a thermal interface paste, a thermal interface sheet, and/or another type of thermal interface material. In some implementations, the thermal interface material of the thermal interface material layers 142 includes a paste that includes metal particles (e.g., gold particles, silver particles) suspended in a liquid compound. In some implementations, the thermal interface material of the thermal interface material layers 142 includes a graphene sheet and/or another type of carbon-based thermal interface material. In some implementations, the thermal interface material of the thermal interface material layers 142 includes a phase change material such as a polymer-based phase change material. In some implementations, the thermal interface material of the thermal interface material layers 142 includes a liquid metal thermal interface material, which may include one or more types of metals (e.g., gallium (Ga), indium (In), tin (Sn)) in liquid form suspended in a compound.

FIG. 1B illustrates an example 144 in which the semiconductor device package 102 is mounted or attached to a mounting structure 146 by the package connectors 118. In some implementations, the mounting structure 146 includes a PCB (e.g., a system board, a motherboard, a riser board, an adapter board). In some implementations, the mounting structure 146 includes sockets in which the package connectors 118 are inserted. In some implementations, the mounting structure 146 includes connectors that are inserted into the package connectors 118.

FIG. 1C illustrates an example 148 of a top view of the semiconductor device package 102. In the top view, the lid 124 of the thermal lid structure 120 is omitted so that the semiconductor dies 106 and the footing 122 on the first side (e.g., the front side) of the package substrate 104 are visible. FIG. 1C also illustrates the location of the cross-section A-A of FIGS. 1A and 1B. As shown in FIG. 1C, the footing 122 has a continuous closed-looped structure (e.g., an approximate ring-shaped structure) above the perimeter of the package substrate 104. The closed-looped structure of the footing 122 defines a space in which the semiconductor dies 106 are located. The lid 124 (not shown) may be coupled with the footing 122 such that the lid 124 spans the space defined by the footing 122.

In some implementations, a top view shape of the package substrate 104 may be approximately rectangular, may be approximately square, or may be another shape. In some implementations, an x-direction dimension of the package substrate 104 and a y-direction dimension of the package substrate 104 are approximately the same size. In some implementations, an x-direction dimension of the package substrate 104 and a y-direction dimension of the package substrate 104 are different sizes.

In some implementations, a top view shape of a semiconductor die 106 may be approximately rectangular, may be approximately square, or may be another shape. In some implementations, an x-direction dimension of a semiconductor die 106 and a y-direction dimension of the semiconductor die 106 are approximately the same size. In some implementations, an x-direction dimension of a semiconductor die 106 and a y-direction dimension of the semiconductor die 106 are different sizes.

In some implementations, a width of the footing 122 may be included in a range of approximately 1 millimeter to approximately 5 millimeters. However, other values for the range are within the scope of the present disclosure. In some implementations, the footing 122 may have a uniform width around the perimeter of the thermal lid structure 120. In some implementations, the footing 122 has one or more segments that have a different width than one or more other segments of the footing 122.

FIG. 1D illustrates an example 150 of a bottom view of the semiconductor device package 102. In the bottom view, the lid 136 of the thermal lid structure 132 is omitted so that the integrated circuit devices 112 and the footing 134 on the second side (e.g., the back side) of the package substrate 104 are visible. FIG. 1D also illustrates the location of the cross-section A-A of FIGS. 1A and 1B. As shown in FIG. 1D, the footing 134 has a continuous closed-looped structure (e.g., an approximate ring-shaped structure) above the second side of the package substrate 104. The closed-looped structure of the footing 134 defines a space in which the integrated circuit devices 112 are located. Thus, the integrated circuit devices 112 are located within the perimeter of the footing 134. In some implementations, one or more of the integrated circuit devices 112 are located adjacent to one or more inner walls of the footing 134. The lid 136 (not shown) may be coupled with the footing 134 such that the lid 136 spans the space defined by the footing 134.

As further shown in FIG. 1D, the package connectors 118 are located outside the perimeter of the footing 134 of the thermal lid structure 132. In some implementations, a package connector 118 may be located adjacent to one or more outer walls of the footing 134. For example, a first package connector 118 may be located adjacent to a first outer wall of the footing 134, and a second package connector 118 may be located adjacent to a second outer wall of the footing 134 opposite the first outer wall. Other arrangements for the package connectors 118 are within the scope of the present disclosure.

In some implementations, the integrated circuit devices 112 are arranged in a grid within the perimeter of the footing 134 of the thermal lid structure 132. However, other arrangements for the integrated circuit devices 112 are within the scope of the present disclosure. One or more segments of the footing 134 of the thermal lid structure 132 may be located between one or more of the integrated circuit devices 112 and a package connector 118.

In some implementations, a top view shape of an integrated circuit device 112 may be approximately rectangular, may be approximately square, or may be another shape. In some implementations, an x-direction dimension of an integrated circuit device 112 and a y-direction dimension of the integrated circuit device 112 are approximately the same size. In some implementations, an x-direction dimension of an integrated circuit device 112 and a y-direction dimension of the integrated circuit device 112 are different sizes.

In some implementations, a top view shape of a package connector 118 may be approximately rectangular, may be approximately square, or may be another shape. In some implementations, an x-direction dimension of a package connector 118 and a y-direction dimension of the package connector 118 are approximately the same size. In some implementations, an x-direction dimension of a package connector 118 and a y-direction dimension of the package connector 118 are different sizes.

In some implementations, a width of the footing 134 may be included in a range of approximately 1 millimeter to approximately 5 millimeters. However, other values for the range are within the scope of the present disclosure. In some implementations, the footing 134 may have a uniform width around the perimeter of the thermal lid structure 132. In some implementations, the footing 134 has one or more segments that have a different width than one or more other segments of the footing 134.

FIG. 1E illustrates another example 152 of a top view of the semiconductor device package 102 in which the footing 134 of the thermal lid structure 132 under the package substrate 104 is illustrated in broken lines to illustrate the relative positions of the footing 134 and the footing 122 of the thermal lid structure 120. As shown in FIG. 1E, an outer perimeter of the footing 134 of the thermal lid structure 132 is located within (e.g., is inside) an outer perimeter of the footing 122 of the thermal lid structure 120. In other words, an outer wall of the footing 134 of the thermal lid structure 132 is located within the perimeter of an outer wall of the footing 122 of the thermal lid structure 120.

An inner perimeter of the footing 134 of the thermal lid structure 132 is located within (e.g., is inside) the outer perimeter of the footing 122, and is also located within (e.g., is inside) an inner perimeter of the footing 122. In other words, an inner wall of the footing 134 is located within the perimeter of the outer wall of the footing 122, as well as within the perimeter of an inner wall of the footing 122. The outer perimeter of the footing 134 may be at least partially within the inner perimeter of the footing 122. For example, one or more segments of the outer wall of the footing 134 may be located within the perimeter of the inner wall of the footing 122. In some implementations, one or more other segments of the outer wall of the footing 134 may be located outside the perimeter of the inner wall of the footing 122.

As indicated above, FIGS. 1A-1E are provided as examples. Other examples may differ from what is described with regard to FIGS. 1A-1E.

FIG. 2 is a diagram of an example 200 of a thermal lid structure described herein. In some implementations, the example 200 include an example of the thermal lid structure 120 described herein. In some implementations, the example 200 include an example of another thermal lid structure described herein, such as a thermal lid structure 620, a thermal lid structure 720, a thermal lid structure 820, and/or a thermal lid structure 920, among other examples.

FIG. 2 illustrates a cross-section view of the thermal lid structure 120. As shown in FIG. 2, the vapor chamber 126 of the thermal lid structure 120 includes an inner cavity 202 within the lid 124 of the thermal lid structure 120. A wicking layer 204 may be included on the walls of the inner cavity 202 to control and facilitate the flow of vapor and liquid within the inner cavity 202.

During operation of the semiconductor device package 102, the semiconductor dies 106 generate heat 206 that is transferred to the lid 124 of the thermal lid structure 120. The heat 206 increases the temperature of the bottom side of the lid 124, which causes liquid within the inner cavity 202 of the vapor chamber 126 to be vaporized into a vapor 208. The vapor 208 rises within the inner cavity 202 toward the top side of the lid 124. The top side of the lid 124 cools the vapor 208 and ejects heat 210 from the vapor 208 through the top side of the lid 124 to the fins 128. This converts the vapor 208 back into a liquid 212, which traverses along the wicking layer 204 back to the bottom of the inner cavity 202. This cycle continues during operation of the semiconductor device package 102 to continuously cool the semiconductor dies 106.

As indicated above, FIG. 2 is provided as an example. Other examples may differ from what is described with regard to FIG. 2.

FIG. 3 is a diagram of an example 300 of a thermal lid structure described herein. In some implementations, the example 300 include an example of the thermal lid structure 132 described herein. In some implementations, the example 300 include an example of another thermal lid structure described herein, such as a thermal lid structure 632, a thermal lid structure 732, a thermal lid structure 832, and/or a thermal lid structure 932, among other examples.

FIG. 3 illustrates a cross-section view of the thermal lid structure 132. As shown in FIG. 3, the vapor chamber 138 of the thermal lid structure 132 includes an inner cavity 302 within the lid 136 of the thermal lid structure 132. A wicking layer 304 may be included on the walls of the inner cavity 302 to control and facilitate the flow of vapor and liquid within the inner cavity 302.

During operation of the semiconductor device package 102, the integrated circuit devices 112 generate heat 306 that is transferred to the lid 136 of the thermal lid structure 132. The heat 306 increases the temperature of the top side of the lid 136, which causes liquid within the inner cavity 302 of the vapor chamber 138 to be vaporized into a vapor 308. The vapor 308 flows toward the bottom of the cavity within the inner cavity 302 toward the bottom side of the lid 136. The bottom side of the lid 136 cools the vapor 308 and ejects heat 310 from the vapor 308 through the bottom side of the lid 136 to the fins 140. This converts the vapor 308 back into a liquid 312, which traverses along the wicking layer 304 back to the top of the inner cavity 302. The wicking layer 304 retains the liquid 312 at the top side of the inner cavity 302 until the liquid 312 is once again converted to vapor 308 by the heat 306. This cycle continues during operation of the semiconductor device package 102 to continuously cool the integrated circuit devices 112.

As indicated above, FIG. 3 is provided as an example. Other examples may differ from what is described with regard to FIG. 3.

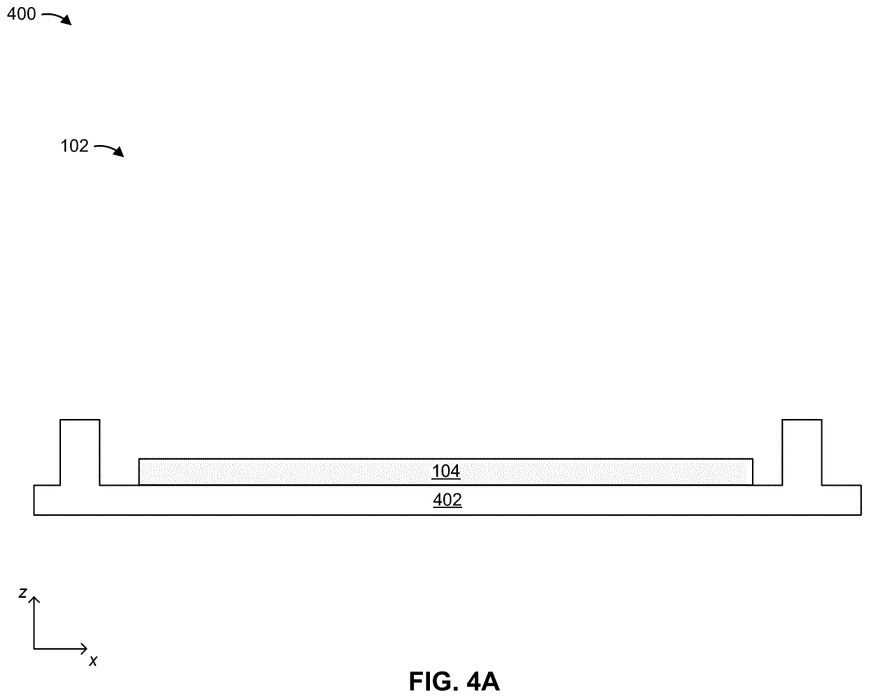

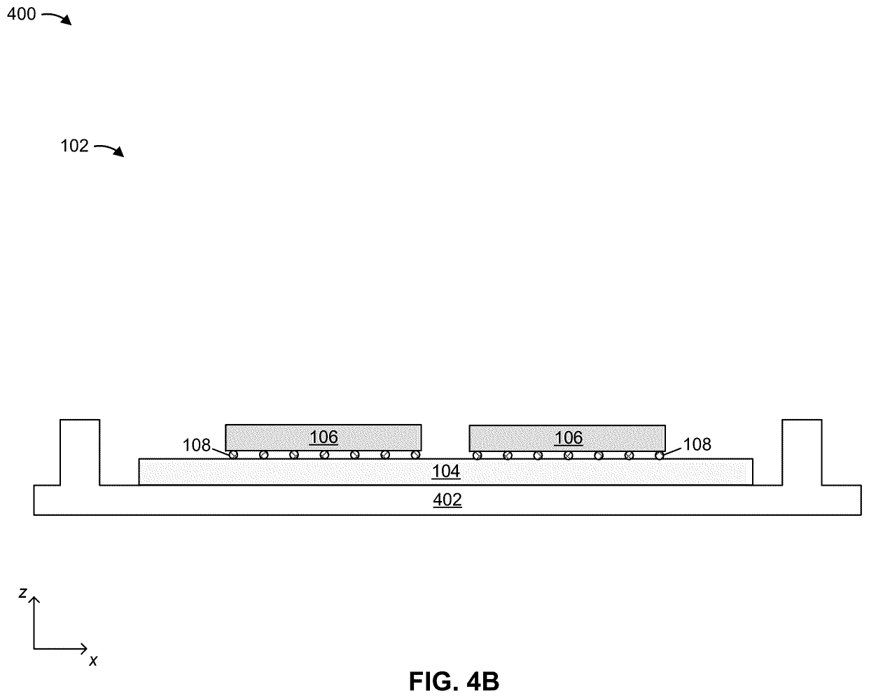

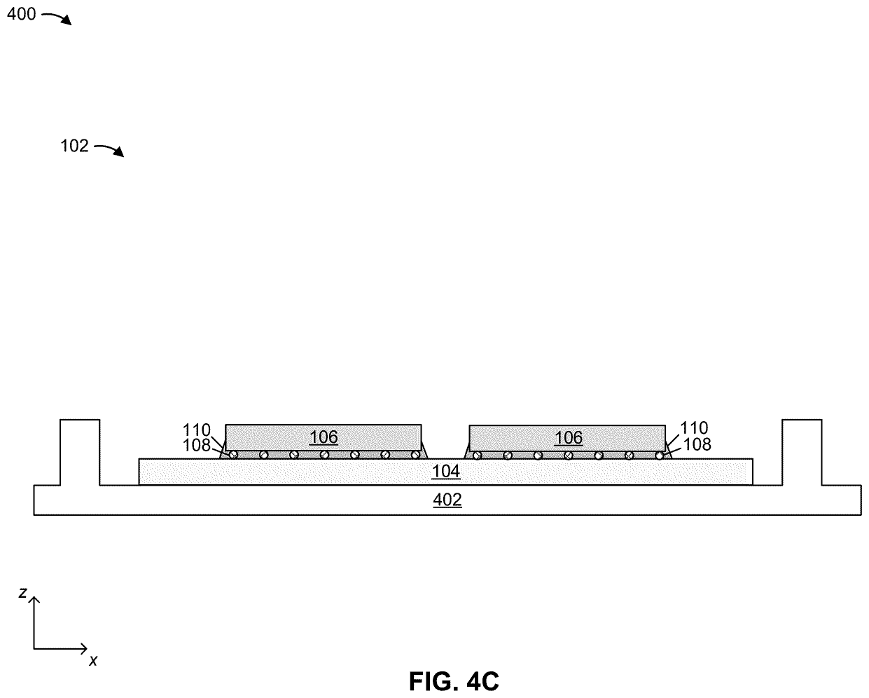

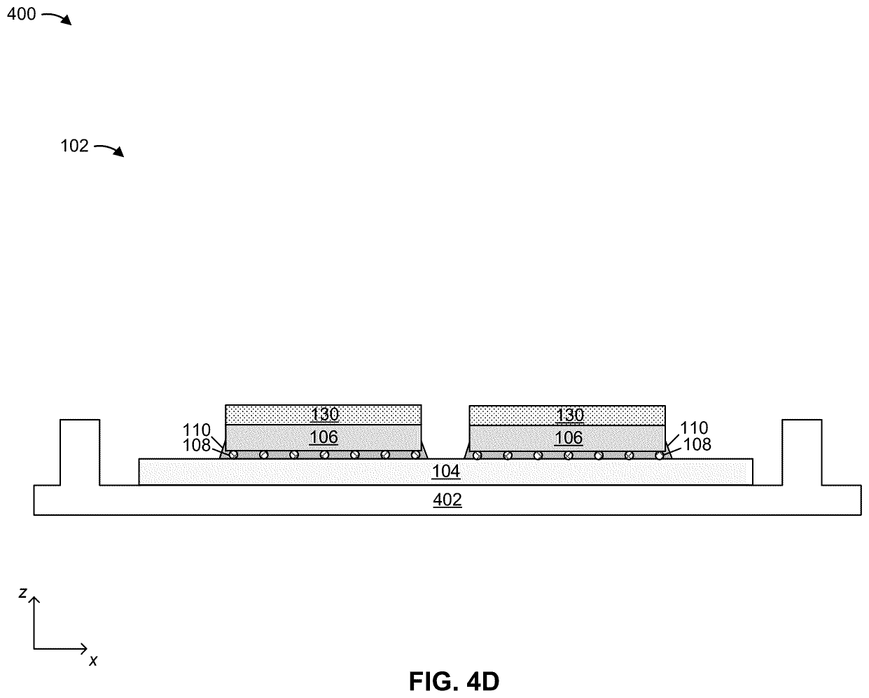

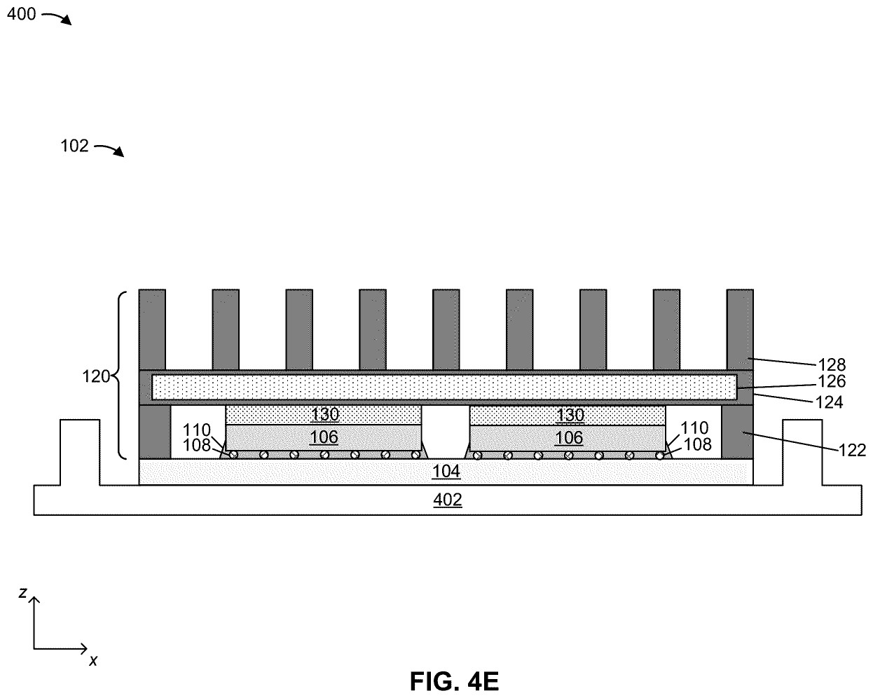

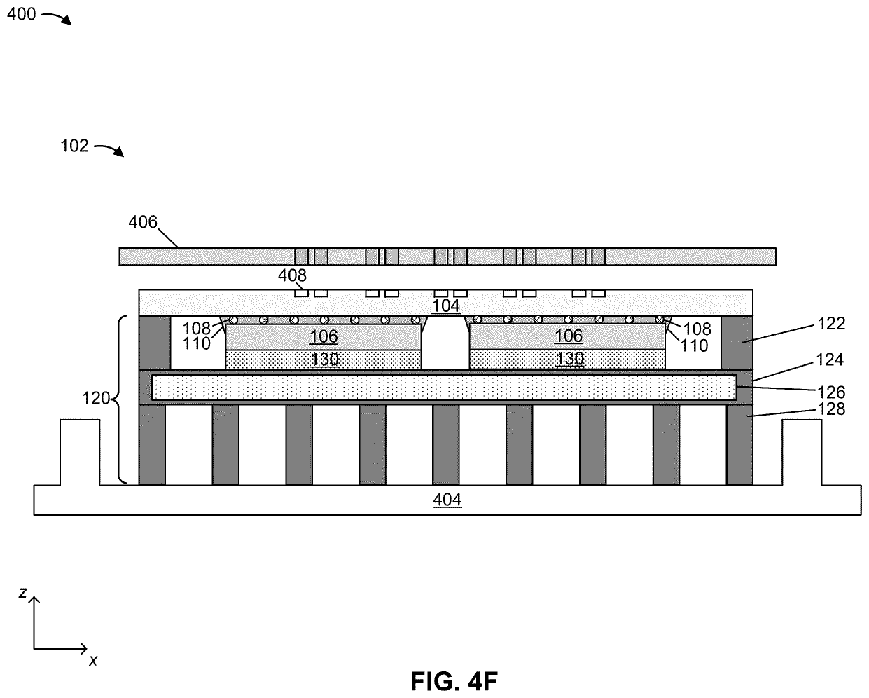

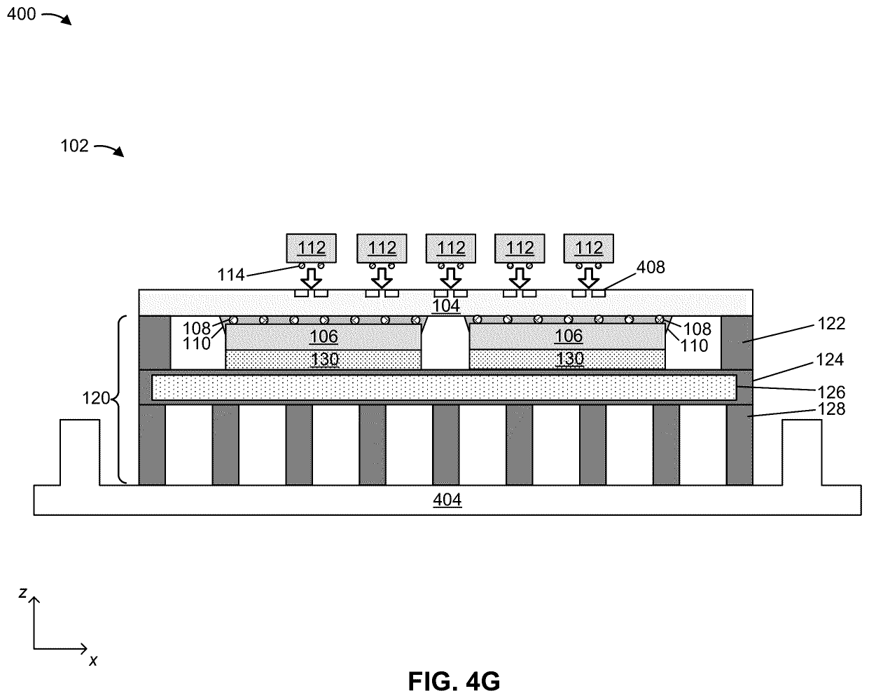

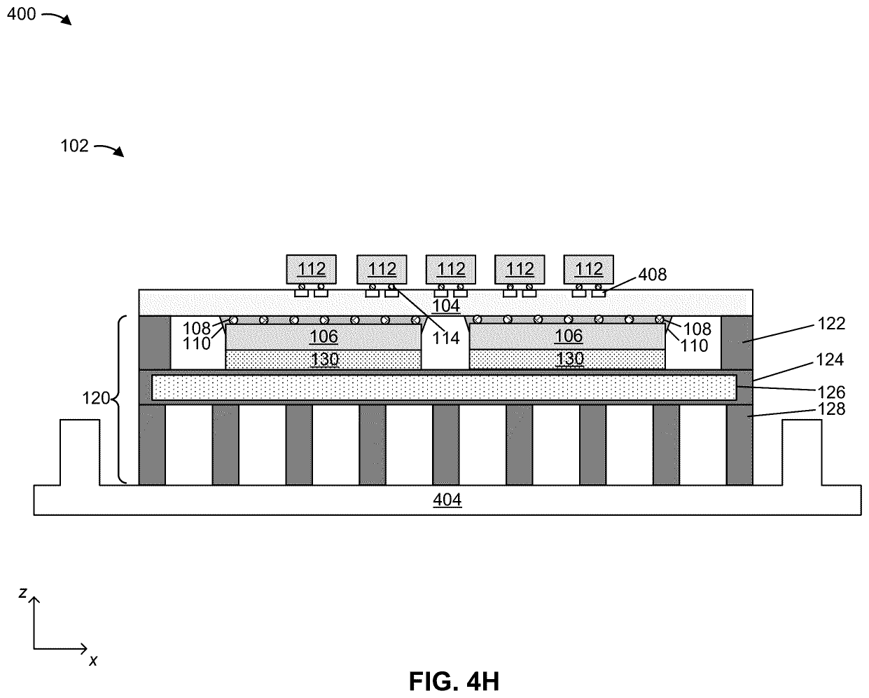

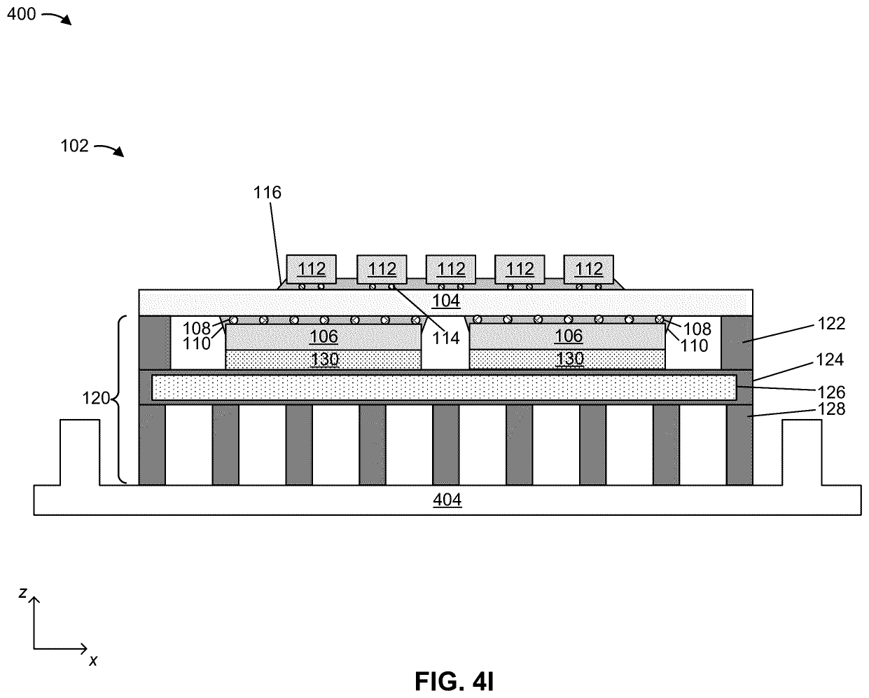

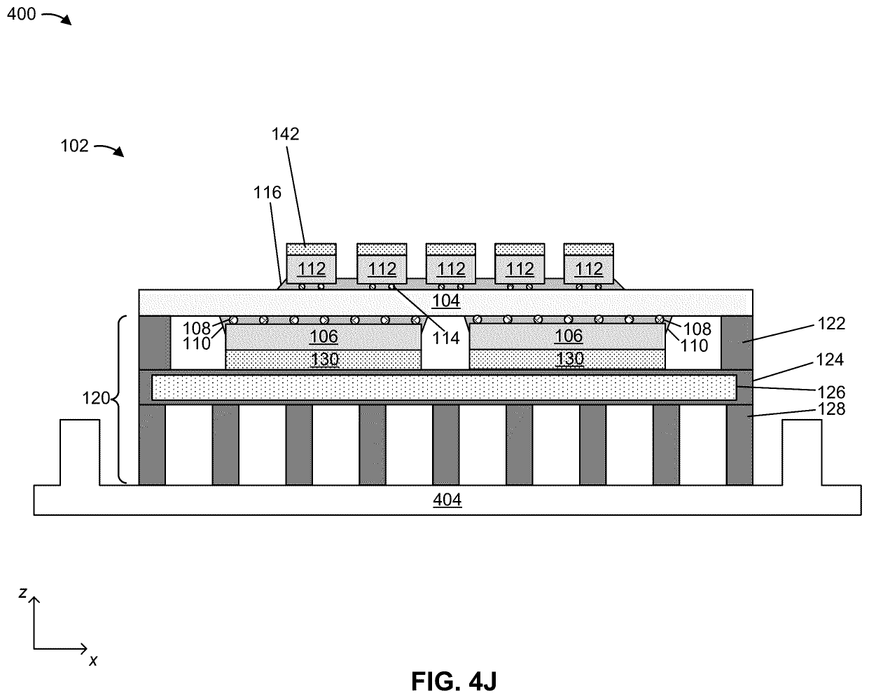

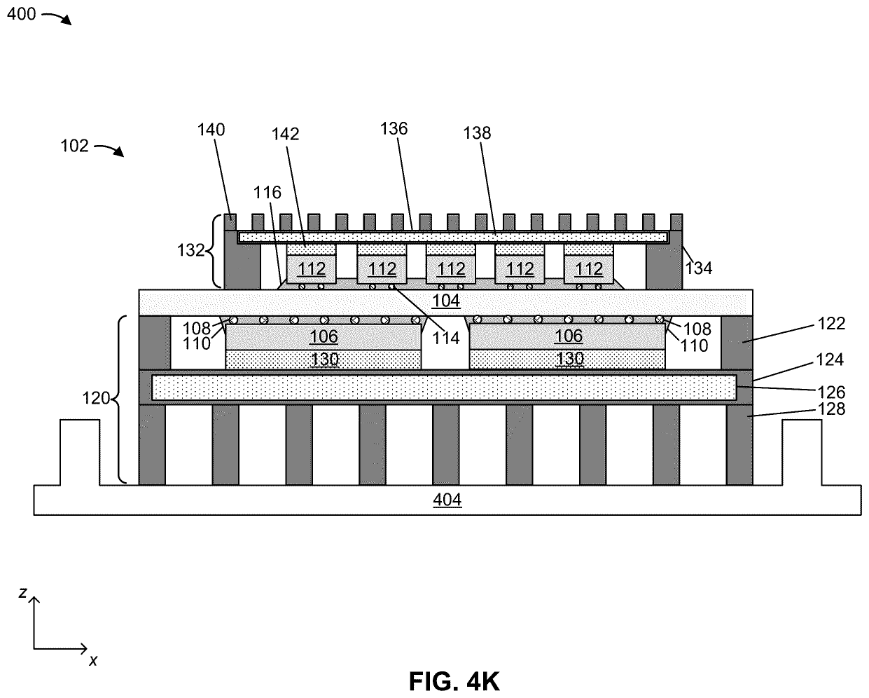

FIGS. 4A-4K are diagrams of an example 400 of forming a semiconductor device package described herein. In some implementations, one or more of the operations described in connection with the example 400 may be performed to form the semiconductor device package 102 described herein. In some implementations, one or more of the operations described in connection with the example 400 may be performed to form another semiconductor device package described herein, such as a semiconductor device package 602, a semiconductor device package 702, a semiconductor device package 802, and/or a semiconductor device package 902, among other examples. In some implementations, of the operations described in connection with the example 400 are performed using one or more packaging tools (e.g., in a semiconductor packaging facility), such as an RDL tool, a connection tool, a pick and place tool, a dispensing tool, a solder mask tool, and/or a solder reflow tool, among other examples.

As shown in FIG. 4A, the package substrate 104 may be placed on a support structure 402. The support structure 402 may include a frame, a tape, a die boat, a conveyor belt, and/or another type of support structure.

As shown in FIG. 4B, semiconductor dies 106 may be placed (e.g., using a pick and place tool) on the first side (e.g., the front side) of the package substrate 104 such that the connection structures 108 are in connect with the package substrate 104. In some implementations, the semiconductor dies 106 are positioned on solder pads on the package substrate 104. The package substrate 104 may then be provided through a solder tool (e.g., a wave solder tool and/or another type of solder tool) to reflow the solder pads to form a bond between the connection structures 108 and the package substrate 104.

As shown in FIG. 4C, after the semiconductor dies 106 are mounted or attached to the package substrate 104, the underfill layers 110 may be dispensed (e.g., using a dispensing tool) around the semiconductor dies 106. The underfill layers 110 may be dispensed such that the underfill layers 110 fill in the gaps around the connection structures 108. In some implementations, underfill layers 110 may be dispensed such that the underfill layers 110 merge between adjacent semiconductor dies 106.

As shown in FIG. 4D, thermal interface material layers 130 may be provided onto the top surfaces of the semiconductor dies 106 (e.g., the surfaces of the semiconductor dies 106 opposite the surfaces of the semiconductor dies 106 that are mounted or attached to the package substrate 104). In some implementations, the thermal interface material layers 130 are dispensed (e.g., using a dispensing tool) onto the semiconductor dies 106 as a paste, as a liquid, or as another flowable material. In some implementations, the thermal interface material layers 130 are placed on the semiconductor dies 106 (e.g., in a sheet form or a pad form). In some implementations, the thermal interface material layers 130 are formed or grown on the semiconductor dies 106.

As shown in FIG. 4E, the thermal lid structure 120 is mounted or attached to the first side (e.g., the front side) of the package substrate 104 such that the lid 124 of the thermal lid structure 120 is placed over the semiconductor dies 106. A pick and place tool or another suitable tool may be used to place the thermal lid structure 120 on the package substrate 104 such that the lid 124 of the thermal lid structure 120 contacts the thermal interface material layers 130 to form a thermal connection between the semiconductor dies 106 and the lid 124 of the thermal lid structure 120 through the thermal interface material layers 130. The footing 122 may be secured to the first side of the package substrate 104 by an adhesive, by an epoxy, by solder pads, and/or by bonding the footing 122 to metal pads on the package substrate 104, among other examples.

As shown in FIG. 4F, the semiconductor device package 102 may be flipped and placed onto another support structure 404 such that the second side (e.g., the bottom side) of the package substrate 104 is facing up. A solder stencil 406 may be used to deposit (e.g., using a dispensing tool) solder paste onto metal pads 408 on the second side of the package substrate 104

As shown in FIG. 4G, the integrated circuit devices 112 may be placed (e.g., using a pick and place tool) onto the second side (e.g., the bottom side) of the package substrate 104. In particular, the connection structures 114 of the integrated circuit devices 112 may be positioned on the solder pads over the metal pads 408 on the second side of the package substrate 104.

As shown in FIG. 4H, the integrated circuit devices 112 may be mounted or attached to the second side of the package substrate 104 by forming bonds form between the connection structures 114 and the metal pads 408 of the package substrate 104. The semiconductor device package 102 may be provided through a solder tool (e.g., a wave solder tool and/or another type of solder tool) to reflow the solder pads to form the bonds between the connection structures 114 and the metal pads 408.

As shown in FIG. 4I, after the integrated circuit devices 112 are mounted or attached to the second side of the package substrate 104, the underfill layer 116 may be dispensed (e.g., using a dispensing tool) around the integrated circuit devices 112. The underfill layer 116 may be dispensed such that the underfill layer 116 fills in the gaps around the connection structures 114 and around the spaces between the integrated circuit devices 112.

As shown in FIG. 4J, thermal interface material layers 142 may be provided onto the top surfaces of the integrated circuit devices 112 (e.g., the surfaces of the integrated circuit devices 112 opposite the surfaces of the integrated circuit devices 112 that are mounted or attached to the package substrate 104). In some implementations, the thermal interface material layers 142 are dispensed (e.g., using a dispensing tool) onto the integrated circuit devices 112 as a paste, as a liquid, or as another flowable material. In some implementations, the thermal interface material layers 142 are placed on the integrated circuit devices 112 (e.g., in a sheet form or a pad form).

In some implementations, the thermal interface material layers 142 are formed or grown on the integrated circuit devices 112.

As shown in FIG. 4K, the thermal lid structure 132 is mounted or attached to the second side (e.g., the bottom side) of the package substrate 104 such that the lid 136 of the thermal lid structure 120 is placed over the integrated circuit devices 112. A pick and place tool or another suitable tool may be used to place the thermal lid structure 132 on the package substrate 104 such that the lid 136 of the thermal lid structure 132 contacts the thermal interface material layers 142 to form a thermal connection between the integrated circuit devices 112 and the lid 136 of the thermal lid structure 132 through the thermal interface material layers 142. The footing 134 may be secured to the second side of the package substrate 104 by an adhesive, by an epoxy, by solder pads, and/or by bonding the footing 134 to metal pads on the package substrate 104, among other examples.

As indicated above, FIGS. 4A-4K are provided as an example. Other examples may differ from what is described with regard to FIGS. 4A-4K. For example, while the example 400 illustrated and described in connection with FIGS. 4A-4K includes mounting or attaching the thermal lid structure 132 after the thermal lid structure 120 is mounted or attached, these operation may be reversed such that the thermal lid structure 120 is mounted or attached after the thermal lid structure 132 is mounted or attached. Other modifications to the order of operations illustrated and described in connection with FIGS. 4A-4K are within the scope of the present disclosure.

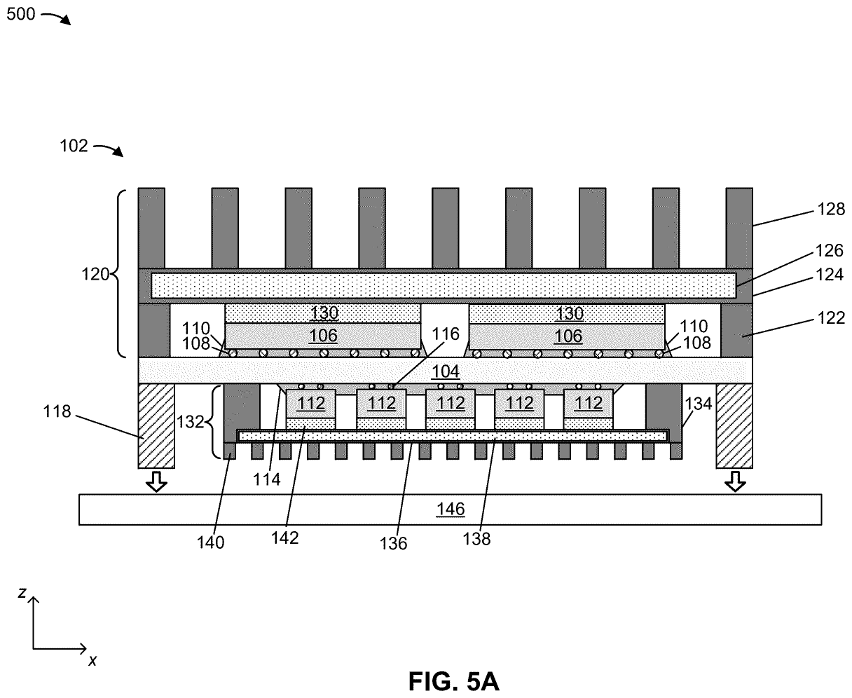

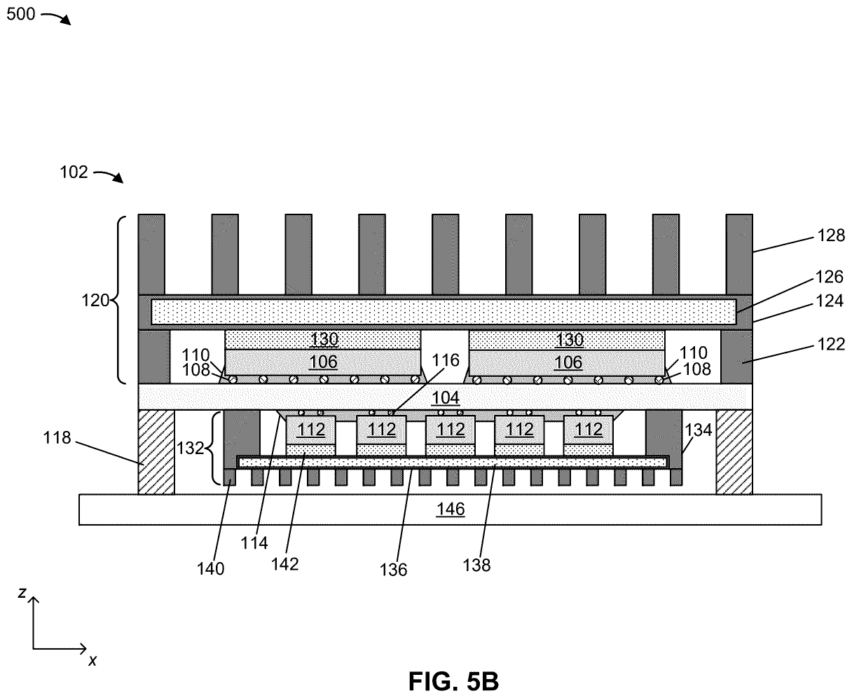

FIGS. 5A and 5B are diagrams of an example 600 of mounting a semiconductor device package described herein to a mounting structure. In some implementations, one or more of the operations described in connection with the example 500 may be performed to mount the semiconductor device package 102 to a mounting structure 146. In some implementations, one or more of the operations described in connection with the example 500 may be performed to mount another semiconductor device package described herein to a mounting structure, such as a semiconductor device package 602, a semiconductor device package 702, a semiconductor device package 802, and/or a semiconductor device package 902, among other examples. In some implementations, of the operations described in connection with the example 500 are performed using one or more packaging tools (e.g., in a semiconductor packaging facility), such as an RDL tool, a connection tool, a pick and place tool, a dispensing tool, a solder mask tool, and/or a solder reflow tool, among other examples.

As shown in FIG. 5A, the package connectors 118 may be mounted or attached to the second side (e.g., the bottom side) of the package substrate 104. The package connectors 118 may be positioned such that one or more of the package connectors 118 are under the footing 122 in the z-direction. Moreover, the package connectors 118 may be positions such that the package connectors 118 are positioned outside and adjacent to the perimeter of the footing 134. The package connectors 118 may be secured to the second side of the package substrate 104 by an adhesive, by an epoxy, by solder pads, sockets, and/or by bonding the package connectors 118 to metal pads on the package substrate 104, among other examples.

As shown in FIGS. 5A and 5B, the semiconductor device package 102 may be mounted or attached to the mounting structure 146 by mounting or attaching the package connectors 118 to the mounting structure 146. In some implementations, the package connectors 118 are placed in sockets on the mounting structure 146. In some implementations, package connectors 118 are soldered to pads on the mounting structure 146. In some implementations, connectors are inserted into the package connectors 118.

As indicated above, FIGS. 5A and 5B are provided as an example. Other examples may differ from what is described with regard to FIGS. 5A and 5B.

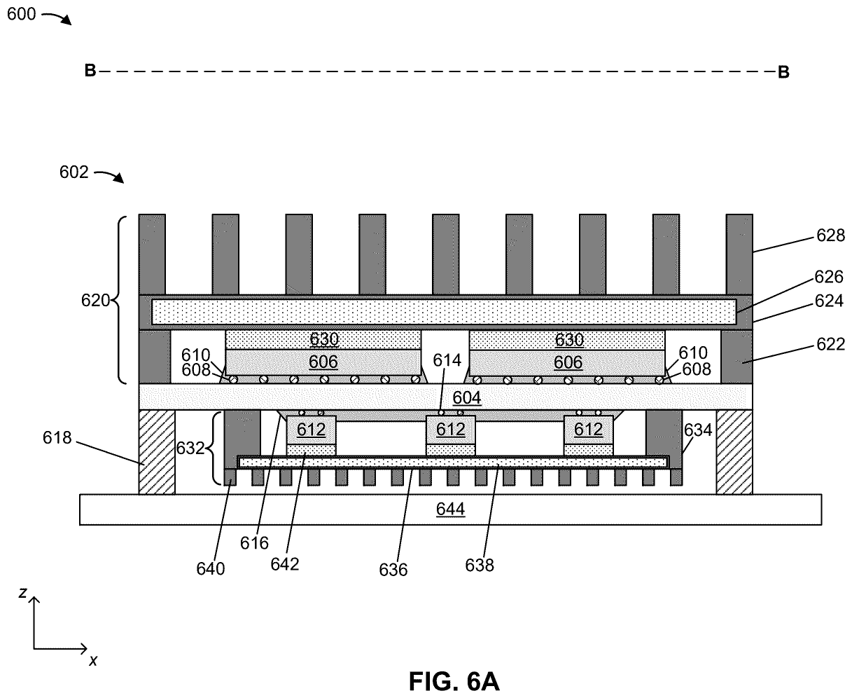

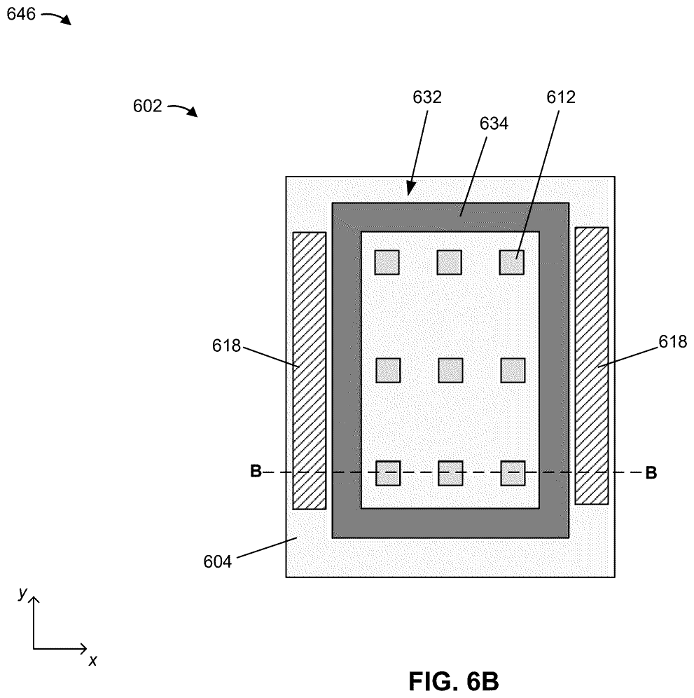

FIGS. 6A and 6B are diagrams of examples of another semiconductor device package described herein. FIG. 6A illustrates a cross-section view of an example 600 of a semiconductor device package 602. As shown in FIG. 6A, the semiconductor device package 602 includes a similar combination and arrangement of components (e.g., devices, structures, and/or layers) 604-642 as the components 104-142 of the semiconductor device package 102. Moreover, the semiconductor device package 602 may be mounted or attached to a mounting structure 644 in a similar manner as the semiconductor device package 102 to the to a mounting structure 146.

The semiconductor device package 602 may differ from the semiconductor device package 102 in that the spacing between integrated circuit devices 612 in the semiconductor device package 602 is greater than the spacing between integrated circuit devices 112 in the semiconductor device package 102. This may provide greater area around the integrated circuit devices 612 for dissipating heat, whereas the spacing between integrated circuit devices 112 in the semiconductor device package 102 may enable a greater density of integrated circuit devices 112 to be included in the semiconductor device package 102.

FIG. 6B illustrates an example 646 of a bottom view of the semiconductor device package 602. In the bottom view, the lid 636 of the thermal lid structure 632 is omitted so that the integrated circuit devices 612 and the footing 634 on the second side (e.g., the back side) of the package substrate 604 are visible. FIG. 6B also illustrates the location of the cross-section B-B of FIG. 6A. As shown in FIG. 6B, the integrated circuit devices 612 are located within the perimeter the continuous closed-looped structure of the footing 634 and are arranged in a grid with greater spacing between adjacent rows and columns of integrated circuit devices 612 than in the semiconductor device package 102.

As indicated above, FIGS. 6A and 6B are provided as examples. Other examples may differ from what is described with regard to FIGS. 6A and 6B.

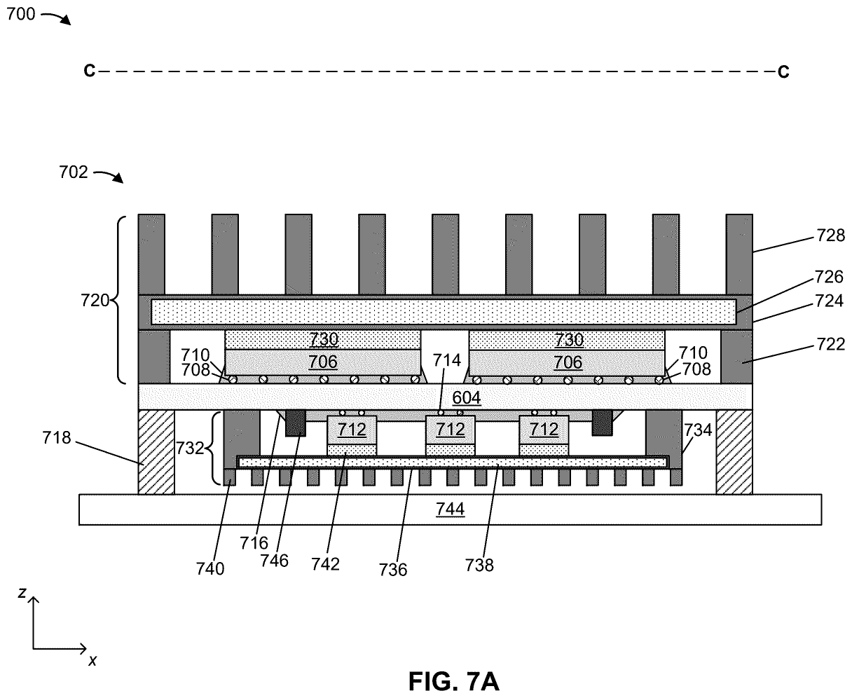

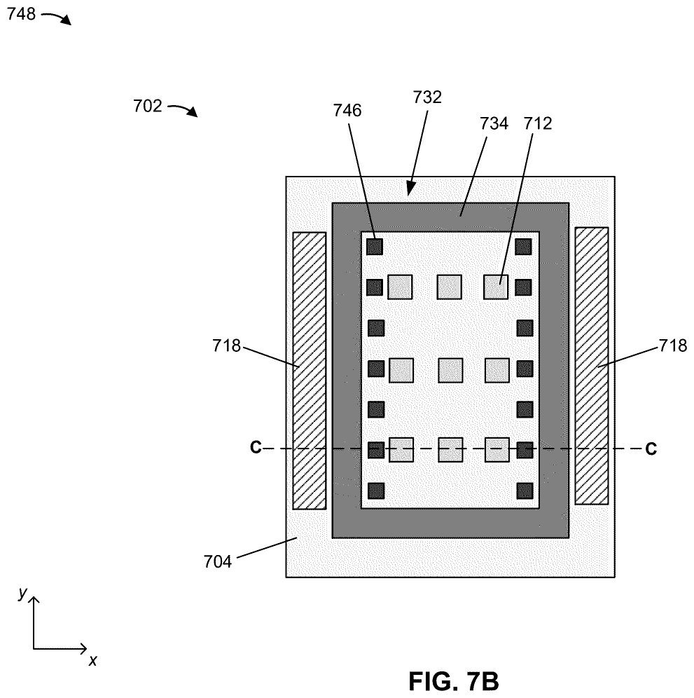

FIGS. 7A and 7B are diagrams of examples of another semiconductor device package described herein. FIG. 7A illustrates a cross-section view of an example 700 of a semiconductor device package 702. As shown in FIG. 7A, the semiconductor device package 702 includes a similar combination and arrangement of components (e.g., devices, structures, and/or layers) 704-742 as the components 104-142 of the semiconductor device package 102. Moreover, the semiconductor device package 702 may be mounted or attached to a mounting structure 744 in a similar manner as the semiconductor device package 102 to the to a mounting structure 146.

As further shown in FIG. 7A, one or more passive circuit devices 746 may be mounted or attached to the second side (e.g., the bottom side) of the package substrate 704. The passive circuit devices 746 may be positioned adjacent to one or more of the integrated circuit devices 712. In the example 700, the passive circuit devices 746 have a smaller z-direction dimension than the integrated circuit devices 712. As a result, the passive circuit devices 746 may be spaced apart from (e.g., is not in physical contact with) the lid 736 of the thermal lid structure 732 by an air gap.

The passive circuit devices 746 may include resistors, capacitors, inductors, diodes, and/or other types of passive circuit devices. In some implementations, one or more passive circuit devices 746 include decoupling capacitors for shunting noise (e.g., voltage spikes, voltage swings) in the power that is delivered to the semiconductor dies 106. In some implementations, one or more passive circuit devices 746 include diodes that are arranged in a passive ESD protection circuit. In some implementations, one or more passive circuit devices 746 include diodes that are arranged in a rectifier circuit for converting between alternating current (AC) and direct current (DC). In some implementations, the passive circuit devices 746 include IPDs that each include a plurality of packaged passive circuit devices.

FIG. 7B illustrates an example 748 of a bottom view of the semiconductor device package 702. In the bottom view, the lid 736 of the thermal lid structure 732 is omitted so that the integrated circuit devices 712 and the footing 734 on the second side (e.g., the back side) of the package substrate 704 are visible. FIG. 7B also illustrates the location of the cross-section C-C of FIG. 7A. As shown in FIG. 7B, the integrated circuit devices 712 and the passive circuit devices 746 are located within the perimeter the continuous closed-looped structure of the footing 134. In some implementations, the passive circuit devices 746 are arranged in one or more rows that are adjacent to one or more sides of the grid in which the integrated circuit devices 712. In some implementations, one or more of the rows of the passive circuit devices 746 are between the integrated circuit devices 712 and one or more segments (e.g., inner walls of the one or more segments) of the footing 134.

As indicated above, FIGS. 7A and 7B are provided as examples. Other examples may differ from what is described with regard to FIGS. 7A and 7B.

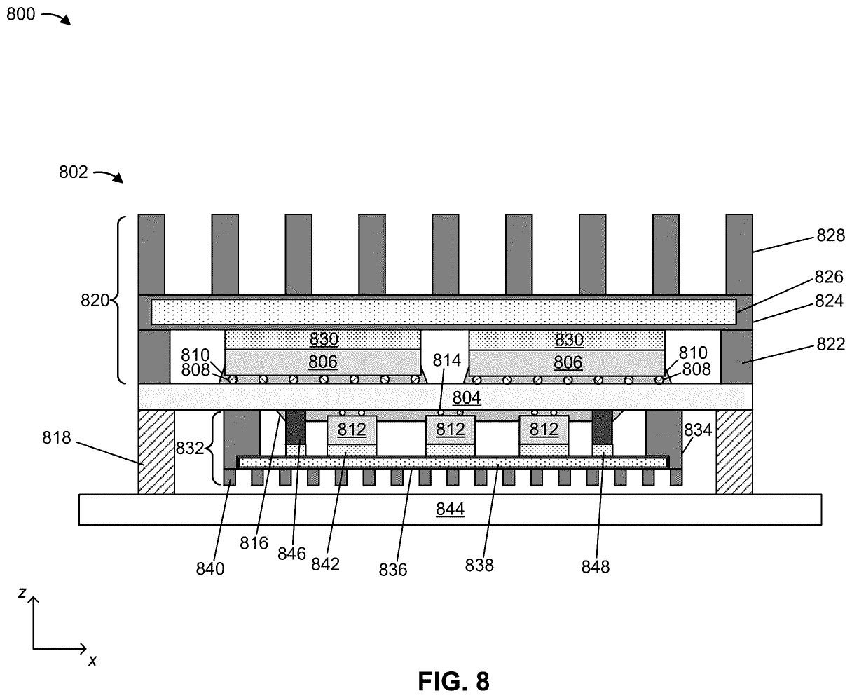

FIG. 8 is a diagram of an example of another semiconductor device package described herein. FIG. 8 illustrates a cross-section view of an example 800 of a semiconductor device package 802. As shown in FIG. 8, the semiconductor device package 802 includes a similar combination and arrangement of components (e.g., devices, structures, and/or layers) 804-842 as the components 104-142 of the semiconductor device package 102. Moreover, the semiconductor device package 802 includes one or more passive circuit devices 846 (similar to the passive circuit devices 746 in the semiconductor device package 702), and may be mounted or attached to a mounting structure 844 in a similar manner as the semiconductor device package 102 to the to a mounting structure 146.

As further shown in FIG. 8, the passive circuit devices 846 differ from the passive circuit devices 746 in that the passive circuit devices 846 are thermally coupled with the lid 836 of the thermal lid structure 832 through thermal interface material layers 848. This enables the passive circuit devices 846 to be cooled by the thermal lid structure 832 in a similar manner as the integrated circuit devices 812.

As indicated above, FIG. 8 is provided as an example. Other examples may differ from what is described with regard to FIG. 8.

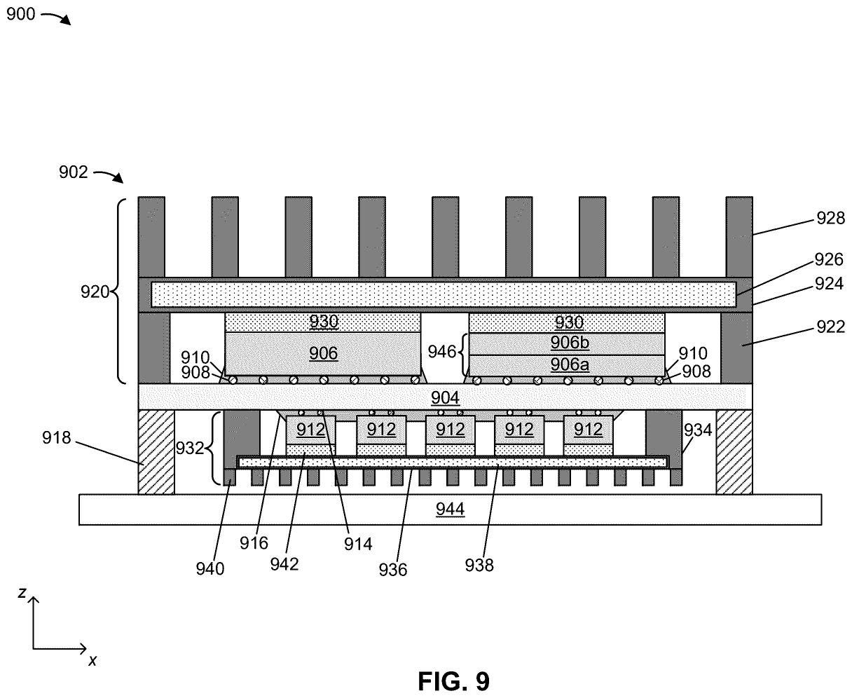

FIG. 9 is a diagram of an example of another semiconductor device package described herein. FIG. 9 illustrates a cross-section view of an example 900 of a semiconductor device package 902. As shown in FIG. 9, the semiconductor device package 902 includes a similar combination and arrangement of components (e.g., devices, structures, and/or layers) 904-942 as the components 104-142 of the semiconductor device package 102. Moreover, the semiconductor device package 902 may be mounted or attached to a mounting structure 944 in a similar manner as the semiconductor device package 102 to the to a mounting structure 146.

As further shown in FIG. 9, one or more of the semiconductor dies 906 may be laterally arranged (e.g., in the x-direction, in the y-direction) on the first side (e.g., the front side) of the package substrate 904 with one or more multiple-die semiconductor die packages 946. In a multiple-die semiconductor die package 946, semiconductor dies 906a and 906b may be stacked and vertically arranged in the z-direction. In some implementations, the semiconductor dies 906a and 906b are directly bonded together by metal-to-metal bonds and dielectric-to-dielectric bonds. In some implementations, the semiconductor dies 906a and 906b are stacked and electrically connected through a die package substrate. In some implementations, the semiconductor dies 906a and 906b are stacked and electrically connected through vias (e.g., through silicon vias (TSVs), through insulator vias (TIVs)). In some implementations, one or more the semiconductor dies 906a and 906b are also horizontally arranged with another semiconductor die in the multiple-die semiconductor die package 946.

As indicated above, FIG. 9 is provided as an example. Other examples may differ from what is described with regard to FIG. 9.

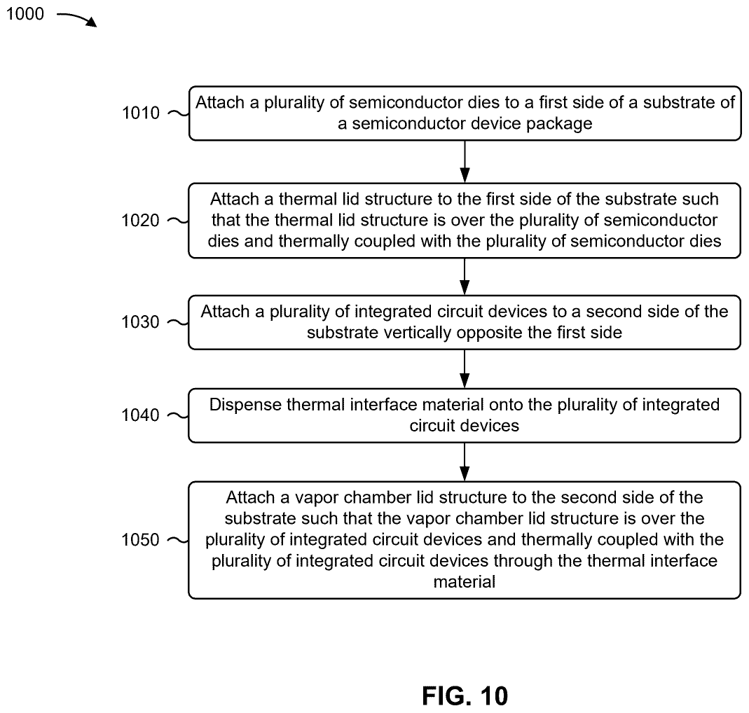

FIG. 10 is a flowchart of an example process 1000 associated with forming a semiconductor device package described herein. In some implementations, one or more process blocks of FIG. 10 are performed using one or more packaging tools, such as an RDL tool, a connection tool, a pick and place tool, a dispensing tool, a solder mask tool, and/or a solder reflow tool, among other examples.

As shown in FIG. 10, process 1000 may include attaching a plurality of semiconductor dies to a first side of a substrate of a semiconductor device package (block 1010). For example, one or more packaging tools may be used to attach a plurality of semiconductor dies (e.g., semiconductor dies 106, 606, 706, 806, 906, and/or 946) to a first side of a substrate (e.g., a package substrate 104, 604, 704, 804, and/or 904) of a semiconductor device package (e.g., a semiconductor device package 102, 602, 702, 802, and/or 902), as described herein.

As further shown in FIG. 10, process 1000 may include attaching a thermal lid structure to the first side of the substrate such that the thermal lid structure is over the plurality of semiconductor dies and thermally coupled with the plurality of semiconductor dies (block 1020). For example, one or more packaging tools may be used to attach a thermal lid structure (e.g., a thermal lid structure 120, 620, 720, 820, and/or 920) to the first side of the substrate such that the thermal lid structure is over the plurality of semiconductor dies and thermally coupled with the plurality of semiconductor dies, as described herein.

As further shown in FIG. 10, process 1000 may include attaching a plurality of integrated circuit devices to a second side of the substrate vertically opposite the first side (block 1030). For example, one or more packaging tools may be used to attach a plurality of integrated circuit devices (e.g., integrated circuit devices 112, 612, 712, 812, and/or 912) to a second side of the substrate vertically opposite (e.g., in a z-direction) the first side, as described herein.

As further shown in FIG. 10, process 1000 may include dispensing thermal interface material onto the plurality of integrated circuit devices (block 1040). For example, one or more packaging tools may be used to dispense thermal interface material (e.g., thermal interface material layers 142, 642, 742, 842, and/or 942) onto the plurality of integrated circuit devices, as described herein.

As further shown in FIG. 10, process 1000 may include attaching a vapor chamber lid structure to the second side of the substrate such that the vapor chamber lid structure is over the plurality of integrated circuit devices and thermally coupled with the plurality of integrated circuit devices through the thermal interface material (block 1050). For example, one or more packaging tools may be used to attach a vapor chamber lid structure (e.g., a thermal lid structure 132, 632, 732, 832, and/or 932) to the second side of the substrate such that the vapor chamber lid structure is over the plurality of integrated circuit devices and thermally coupled with the plurality of integrated circuit devices through the thermal interface material, as described herein.

Process 1000 may include additional implementations, such as any single implementation or any combination of implementations described below and/or in connection with one or more other processes described elsewhere herein.

In a first implementation, process 1000 includes dispensing underfill material (e.g., 116, 616, 716, 816, and/or 916) between the plurality of integrated circuit devices and the second side of the substrate, where dispensing the thermal interface material onto the plurality of integrated circuit devices includes dispensing the thermal interface material onto the plurality of integrated circuit devices after dispensing the underfill material between the plurality of integrated circuit devices and the second side of the substrate.

In a second implementation, process 1000 includes attaching a plurality of passive circuit devices (e.g., passive circuit devices 746 and/or 846) to the second side of the substrate, where attaching the vapor chamber lid structure to the second side of the substrate includes attaching the vapor chamber lid structure to the second side of the substrate such that the vapor chamber lid structure is over the plurality of passive circuit devices.

In a third implementation, the plurality of passive circuit devices are positioned between the plurality of integrated circuit devices and a lid wall (e.g., a footing 134, 634, 734, 834, and/or 934) of the vapor chamber lid structure.

In a fourth implementation, attaching the plurality of integrated circuit devices to the second side of the substrate and attaching the vapor chamber lid structure to the second side of the substrate include attaching, after attaching the plurality of semiconductor dies and attaching the thermal lid structure to the first side of the substrate, the plurality of integrated circuit devices to the second side of the substrate and attaching the vapor chamber lid structure to the second side of the substrate.

In a fifth implementation, process 1000 includes attaching the semiconductor device package to a mounting structure (e.g., a mounting structure 146, 644, 744, 844, and/or 944), where the vapor chamber lid structure is located between the substrate and the mounting structure.

Although FIG. 10 shows example blocks of process 1000, in some implementations, process 1000 includes additional blocks, fewer blocks, different blocks, or differently arranged blocks than those depicted in FIG. 10. Additionally, or alternatively, two or more of the blocks of process 1000 may be performed in parallel.

In this way, thermal management components are included over semiconductor components on both sides of a package substrate of a semiconductor device package to provide two-sided thermal management system for the semiconductor device package. Semiconductor components may be mounted or attached to the top side of the package substrate, and semiconductor components may be mounted or attached to the bottom side of the package substrate. Thermal management components such as heatsinks, fins, vapor chamber lid structures, and/or other types of thermal management components may be included over the semiconductor components on the top side and over the semiconductor components on the bottom side of the package substrate. In this way, the two-sided thermal management system of the semiconductor device package enables heat to be dissipated from the semiconductor components on both sides of the package substrate of the semiconductor device package. This enables the semiconductor components on both sides of the package substrate of the semiconductor device package to operate at lower temperatures, which may increase the performance of the semiconductor components, may enable the performance of the semiconductor components to be sustained for longer time durations, and/or may increase the reliability and longevity of the semiconductor components, among other examples.

As described in greater detail above, some implementations described herein provide a semiconductor device package. The semiconductor device package includes a substrate. The semiconductor device package includes a plurality of semiconductor dies on a first side of the substrate. The semiconductor device package includes a plurality of integrated circuit devices on a second side of the substrate opposite the first side. The semiconductor device package includes a first vapor chamber lid structure over the plurality of semiconductor dies and thermally coupled with the plurality of semiconductor dies. The semiconductor device package includes a second vapor chamber lid structure over the plurality of integrated circuit devices and thermally coupled with the plurality of integrated circuit devices.

As described in greater detail above, some implementations described herein provide a semiconductor device package. The semiconductor device package includes a substrate. The semiconductor device package includes a plurality of semiconductor dies on a front side of the substrate. The semiconductor device package includes a plurality of voltage regulator integrated circuit devices on a back side of the substrate opposing the front side. The semiconductor device package includes a first vapor chamber lid structure over the plurality of semiconductor dies and thermally coupled with the plurality of semiconductor dies. The semiconductor device package includes a second vapor chamber lid structure over the plurality of voltage regulator integrated circuit devices and thermally coupled with the plurality of voltage regulator integrated circuit devices. The semiconductor device package includes one or more package connectors on the back side of the substrate, where the one or more package connectors are located outside of a perimeter of the second vapor chamber lid structure.

As described in greater detail above, some implementations described herein provide a method. The method includes attaching a plurality of semiconductor dies to a first side of a substrate of a semiconductor device package. The method includes attaching a thermal lid structure to the first side of the substrate such that the thermal lid structure is over the plurality of semiconductor dies and thermally coupled with the plurality of semiconductor dies. The method includes attaching a plurality of integrated circuit devices to a second side of the substrate vertically opposite the first side. The method includes dispensing thermal interface material onto the plurality of integrated circuit devices. The method includes attaching a vapor chamber lid structure to the second side of the substrate such that the vapor chamber lid structure is over the plurality of integrated circuit devices and thermally coupled with the plurality of integrated circuit devices through the thermal interface material.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device package, comprising:
a substrate;
a plurality of semiconductor dies on a first side of the substrate;
a plurality of integrated circuit devices on a second side of the substrate opposite the first side;
a first vapor chamber lid structure over the plurality of semiconductor dies and thermally coupled with the plurality of semiconductor dies; and
a second vapor chamber lid structure over the plurality of integrated circuit devices and thermally coupled with the plurality of integrated circuit devices.

2. The semiconductor device package of claim 1, wherein the plurality of integrated circuit devices comprise a plurality of voltage regulator module (VRM) integrated circuit devices; and
wherein the plurality of VRM integrated circuit devices are thermally coupled with the second vapor chamber lid structure by thermal interface material.

3. The semiconductor device package of claim 1, wherein the second vapor chamber lid structure comprises:
a footing having a continuous closed-looped structure that defines a space in which the plurality of integrated circuit devices are located;
a lid coupled with the footing and spanning the space defined by the footing,
wherein the lid is thermally coupled with the plurality of integrated circuit devices; and
a vapor chamber within the lid.

4. The semiconductor device package of claim 3, wherein the plurality of integrated circuit devices are thermally coupled with a first side of the lid; and
wherein the second vapor chamber lid structure further comprises a plurality of fins that are physically coupled with a second side of the lid opposing the first side.

5. The semiconductor device package of claim 3, wherein the first vapor chamber lid structure comprises:
another footing having a continuous closed-looped structure that defines a space in which the plurality of semiconductor dies are located,
wherein an outer perimeter of the footing of the second vapor chamber lid structure is located within an outer perimeter of the other footing of the first vapor chamber lid structure.

6. The semiconductor device package of claim 5, wherein an inner perimeter of the footing of the second vapor chamber lid structure is located within an inner perimeter of the other footing of the first vapor chamber lid structure.

7. The semiconductor device package of claim 1, wherein a footing of the first vapor chamber lid structure is coupled to the first side of the substrate; and
wherein a footing of the second vapor chamber lid structure is coupled to the second side of the substrate.

8. A semiconductor device package, comprising:
a substrate;
a plurality of semiconductor dies on a front side of the substrate;
a plurality of voltage regulator integrated circuit devices on a back side of the substrate opposing the front side;
a first vapor chamber lid structure over the plurality of semiconductor dies and thermally coupled with the plurality of semiconductor dies;
a second vapor chamber lid structure over the plurality of voltage regulator integrated circuit devices and thermally coupled with the plurality of voltage regulator integrated circuit devices; and
one or more package connectors on the back side of the substrate,
wherein the one or more package connectors are located outside of a perimeter of the second vapor chamber lid structure.

9. The semiconductor device package of claim 8, wherein the perimeter of the second vapor chamber lid structure is at least partially within a perimeter of the first vapor chamber lid structure.

10. The semiconductor device package of claim 8, wherein the first vapor chamber lid structure comprises a lid wall around a perimeter of the substrate and is coupled to a portion of the front side of the substrate; and
wherein the one or more package connectors are located under the portion of the front side of the substrate to which the lid wall is coupled such that the lid wall and the one or more package connectors are vertically arranged in the semiconductor device package.

11. The semiconductor device package of claim 8, further comprising:
one or more integrated passive devices (IPDs) on the back side of the substrate and laterally adjacent to the plurality of voltage regulator integrated circuit devices.

12. The semiconductor device package of claim 11, wherein the one or more IPDs are spaced apart from the second vapor chamber lid structure by an air gap.

13. The semiconductor device package of claim 11, wherein the one or more IPDs are thermally coupled to the second vapor chamber lid structure.

14. The semiconductor device package of claim 8, wherein at least a subset of the plurality of semiconductor dies comprise a multiple-die semiconductor die package in which two or more of the plurality of semiconductor dies are directly bonded and vertically arranged.

15. A method, comprising:
attaching a plurality of semiconductor dies to a first side of a substrate of a semiconductor device package;
attaching a thermal lid structure to the first side of the substrate such that the thermal lid structure is over the plurality of semiconductor dies and thermally coupled with the plurality of semiconductor dies;
attaching a plurality of integrated circuit devices to a second side of the substrate vertically opposite the first side;
dispensing thermal interface material onto the plurality of integrated circuit devices; and
attaching a vapor chamber lid structure to the second side of the substrate such that the vapor chamber lid structure is over the plurality of integrated circuit devices and thermally coupled with the plurality of integrated circuit devices through the thermal interface material.

16. The method of claim 15, further comprising:
dispensing underfill material between the plurality of integrated circuit devices and the second side of the substrate,
wherein dispensing the thermal interface material onto the plurality of integrated circuit devices comprises:
dispensing the thermal interface material onto the plurality of integrated circuit devices after dispensing the underfill material between the plurality of integrated circuit devices and the second side of the substrate.

17. The method of claim 15, further comprising:
attaching a plurality of passive circuit devices to the second side of the substrate,
wherein attaching the vapor chamber lid structure to the second side of the substrate comprises:
attaching the vapor chamber lid structure to the second side of the substrate such that the vapor chamber lid structure is over the plurality of passive circuit devices.

18. The method of claim 17, wherein the plurality of passive circuit devices are positioned between the plurality of integrated circuit devices and a lid wall of the vapor chamber lid structure.

19. The method of claim 15, wherein attaching the plurality of integrated circuit devices to the second side of the substrate and attaching the vapor chamber lid structure to the second side of the substrate comprise:
attaching, after attaching the plurality of semiconductor dies and attaching the thermal lid structure to the first side of the substrate, the plurality of integrated circuit devices to the second side of the substrate and attaching the vapor chamber lid structure to the second side of the substrate.

20. The method of claim 15, further comprising:
attaching the semiconductor device package to a mounting structure,
wherein the vapor chamber lid structure is located between the substrate and the mounting structure.
